(19) United States
(12) Patent Application Publication
(10) Pub. No.: US 2026/0368616 A1
(43) Pub. Date: Nov. 19, 2026

(54) SUBSTRATE PROCESSING APPARATUS, ESTIMATION METHOD, METHOD FOR GENERATING TRAINING DATA, TRAINING METHOD, TRAINING APPARATUS, METHOD FOR GENERATING TRAINED MODEL, AND TRAINED MODEL

(71) Applicant: SCREEN Holdings Co., Ltd., Kyoto (JP)

(72) Inventors: Yusuke KUBO, Kyoto-shi, Kyoto (JP); Takeru NAKAMURA, Kyoto-shi, Kyoto (JP); Takeshi SARUWATARI, Kyoto-shi, Kyoto (JP)

(21) Appl. No.: 19/148,098

(22) PCT Filed: Nov. 27, 2023
(86) PCT No.: PCT/JP2023/042335

§ 371 Date: Jul. 15, 2025

(30) Foreign Application Priority Data
Jan. 26, 2023 (JP) 2023-010237

(51) Int. Cl. G06N 20/00

(52) U.S. Cl. CPC G06N 20/00

(57) ABSTRACT

A substrate processing apparatus includes a processing chamber, a first processing sensor, and a controller. The first processing sensor detects at least one of a wind speed and a wind direction at a first position during processing in or around the processing chamber. The controller is configured or programmed to input a detection result obtained by the first processing sensor to a trained model and acquire at least one of the estimated wind speed and the estimated wind direction at a second position during processing. The trained model is generated by machine training based on a first detection result obtained by the first training sensor at a first position during training and a second detection result of the second training sensor at a second position during training.

### TECHNICAL FIELD

The present invention relates to a substrate processing apparatus, an estimation method, a method of generating training data, a training method, a training apparatus, a method of generating a trained model, and a trained model.

### BACKGROUND ART

A substrate processing apparatuses that processes substrates has been known. A substrate processing apparatus is suitably used for manufacturing a semiconductor substrate. The substrate processing apparatus processes substrate using a processing liquid such as a chemical liquid in a chamber. In such a substrate processing apparatus, for example, when the wind speed or the wind direction around the substrate changes, the substrate processing may be affected. Therefore, for example, it is conceivable to monitor the wind speed or the wind direction by placing a sensor that detects the wind speed or the wind direction around the substrate. If, however, the chemical liquid discharged from the substrate adheres to the sensor, the sensor deteriorates, and thus the sensor cannot be placed around the substrate. Therefore, the wind speed or the wind direction around the substrate cannot be detected.

Here, for example, Patent Literature 1 describes a method of estimating a wind speed distribution in an entire room by simulating an air flow on the basis of wind speed/temperature information measured by a sensor disposed in the room.

### CITATION LIST

### Patent Literature

Patent Literature 1: Japanese Patent Application Publication No. 2012-63055

### SUMMARY OF INVENTION

### Technical Problem

However, in the method described in Patent Literature 1, since simulation is performed for the entire room, there is a problem that it takes time to make an estimation.

The present invention has been made in view of the above problems, and an object of the present invention is to provide a substrate processing apparatus, an estimation method, a method of generating training data, a training method, a training apparatus, a method of generating a trained model, and a trained model which can shorten the time for estimating a wind speed or a wind direction at a predetermined position in a chamber.

### Solution to Problem

According to one aspect of the present invention, a substrate processing apparatus includes a substrate holding portion, a processing chamber, a first processing sensor, and a controlling portion. The substrate holding portion holds and rotates a processing target substrate. The processing chamber accommodates the substrate holding portion. The first processing sensor is disposed in or around the processing chamber. The first processing sensor detects at least one of a wind speed and a wind direction at a first position during processing in or around the processing chamber. The controlling portion inputs a detection result obtained by the first processing sensor to the trained model and acquires at least one of an estimated wind speed and an estimated wind direction at a second position during processing in the processing chamber. The trained model is generated by machine training based on a first detection result obtained by a first training sensor that detects at least one of the wind speed and the wind direction at the first position during training in or around a training chamber and a second detection result obtained by a second training sensor that detects at least one of the wind speed and the wind direction at the second position during training in the training chamber.

In a preferred embodiment, a substrate processing apparatus includes a cleaning liquid supplying portion that supplies a cleaning liquid to the processing target substrate. The controlling portion inputs the detection result obtained by the first processing sensor at the time of cleaning to the trained model and acquires at least one of the estimated wind speed and the estimated wind direction at the time of cleaning.

In a preferred embodiment, a substrate processing apparatus includes a cup that is disposed around the substrate holding portion and receives a processing liquid discharged from the processing target substrate. The second position during processing is a position on the cup.

In a preferred embodiment, the trained model is generated by machine training based on the first detection result and the second detection result indicated using a three-dimensional orthogonal coordinate system. The controlling portion inputs the detection result obtained by the first processing sensor indicated using a three-dimensional orthogonal coordinate system to the trained model and acquires at least one of the estimated wind speed and the estimated wind direction indicated using the three-dimensional orthogonal coordinate system.

In a preferred embodiment, the trained model has a regression model for each of three coordinates. The controlling portion inputs the detection result obtained by the first processing sensor indicated using a three-dimensional orthogonal coordinate system to each of the regression models and acquires the estimated wind speed for each of the three coordinates.

In a preferred embodiment, a substrate processing apparatus includes a display portion that displays at least one of the estimated wind speed and the estimated wind direction.

In a preferred embodiment, the controlling portion causes the display portion to display at least one of the acquired estimated wind speed and estimated wind direction by using a coordinate system based on each of the second training sensors.

In a preferred embodiment, a substrate processing apparatus includes an input portion to which a processing condition for processing the processing target substrate are input. The processing condition that can change at least one of the estimated wind speed and the estimated wind direction is input to the input portion.

In a preferred embodiment, the substrate processing apparatus includes a processing detecting portion. The processing detecting portion detects at least one of the atmospheric pressure in or around the processing chamber, the rotation speed of the processing target substrate, the flow rate or the supply pressure of the gas supplied into the processing chamber, and the flow rate or the exhaust pressure of the gas discharged from the processing chamber. The trained model is generated by machine training based on the first detection result, the second detection result, and the detection result obtained by the training detecting portion. The training detecting portion detects at least one of the atmospheric pressure in or around the training chamber, the rotation speed of a training target substrate, the flow rate or the supply pressure of the gas supplied into the training chamber, and the flow rate or the exhaust pressure of the gas discharged from the training chamber. The controlling portion inputs the detection result obtained by the first processing sensor and the detection result obtained by the processing detecting portion to the trained model and acquires at least one of the estimated wind speed and the estimated wind direction at the second position during processing.

According to another aspect of the present invention, an estimation method includes a step of detecting at least one of a wind speed and a wind direction at a first position during processing in or around a processing chamber accommodating a substrate holding portion that holds and rotates a processing target substrate and a step of inputting the detection result of detecting at least one of the wind speed and the wind direction to a trained model and acquiring at least one of an estimated wind speed and an estimated wind direction at a second position during processing in the processing chamber. The trained model is generated by machine training based on the first detection result obtained by the first training sensor that detects at least one of the wind speed and the wind direction at the first position during training in or around a training chamber and the second detection result obtained by the second training sensor that detects at least one of the wind speed and the wind direction at the second position during training in the training chamber.

According to another aspect of the present invention, a method of generating training data includes a step of acquiring a first detection result of detecting at least one of a wind speed and a wind direction at a first position during training in a training chamber accommodating a substrate holding portion or around the training chamber, a step of acquiring a second detection result of detecting at least one of a wind speed and a wind direction at a second position during training in the training chamber, and a step of storing the first detection result and the second detection result in association with each other in a storage portion as training data.

According to another aspect of the present invention, a training method includes a step of acquiring training data generated according to the above method of generating training data and a step of performing machine training by inputting the training data to a training program.

According to another aspect of the present invention, a training apparatus includes a storage portion that stores training data generated according to the above method of generating training data and a training portion that performs machine training by inputting the training data to a training program.

According to another aspect of the present invention, a method of generating a trained model includes a step of acquiring training data generated according to the above method of generating training data and a step of generating a trained model by machine training based on the training data.

According to another aspect of the present invention, the trained model is generated by machine training based on training data generated according to the above method of generating training data.

### Advantageous Effects of Invention

According to the present invention, it is possible to provide a substrate processing apparatus, an estimation method, a method of generating training data, a training method, a training apparatus, a method of generating a trained model, and a trained model which can shorten the time for estimating a wind speed or a wind direction at a predetermined position in a chamber.

### BRIEF DESCRIPTION OF DRAWINGS

FIG. 1 is a diagram illustrating the overall configuration of a substrate processing training system according to a first preferred embodiment.

FIG. 2 is a schematic diagram of the substrate processing apparatus according to the first preferred embodiment.

FIG. 3 is a schematic diagram of a processing unit according to the first preferred embodiment.

FIG. 4 is a perspective view schematically illustrating a processing unit 10 of the substrate processing apparatus according to the first preferred embodiment.

FIG. 5 is a perspective view schematically illustrating a processing unit 10L of the substrate processing apparatus according to the first preferred embodiment.

FIG. 6 is a block diagram showing part of a substrate processing apparatus 100 according to the first preferred embodiment.

FIG. 7 is a flowchart illustrating a substrate processing method by the substrate processing apparatus according to the first preferred embodiment.

FIG. 8 is a flowchart illustrating a method of estimating a wind speed and a wind direction at a second position during processing by the substrate processing apparatus.

FIG. 9 is a block diagram showing part of a substrate processing apparatus 100L according to the first preferred embodiment.

FIG. 10 is a block diagram illustrating a training data generation apparatus.

FIG. 11 is a diagram illustrating an example of the training data generated by the training data generation apparatus.

FIG. 12 is a flowchart illustrating a method of generating training data according to the first preferred embodiment.

FIG. 13 is a block diagram illustrating a training apparatus.

FIG. 14 is a flowchart illustrating a training method and a method of generating a trained model according to the first preferred embodiment.

FIG. 15 is a diagram illustrating a trained model according to Modified Example 2.

FIG. 16 is a diagram showing an example of a coordinate system based on a processing chamber according to Modified Example 3.

FIG. 17 is a diagram illustrating an example of a coordinate system based on each of second training sensors according to Modified Example 3.

FIG. 18 is a diagram showing an example of an image showing an estimated wind speed and an estimated wind direction using a coordinate system based on each of the second training sensors according to Modified Example 3.

FIG. 19 is a schematic diagram of a processing unit according to a second preferred embodiment.

FIG. 20 is a schematic diagram of the processing unit of a substrate processing apparatus according to the second preferred embodiment.

### DESCRIPTION OF PREFERRED EMBODIMENTS

The preferred embodiments of the present invention will be described below with reference to the accompanying drawings. However, the present invention is not restricted to the preferred embodiments described below and can be implemented in various modes within a scope not deviating from its gist. It is noted that, for portions for which description is redundant, the description is at times omitted as appropriate. In addition, portions that are the same or are corresponding portions in the figures shall be denoted by the same reference signs and descriptions shall not be repeated.

### First Preferred Embodiment

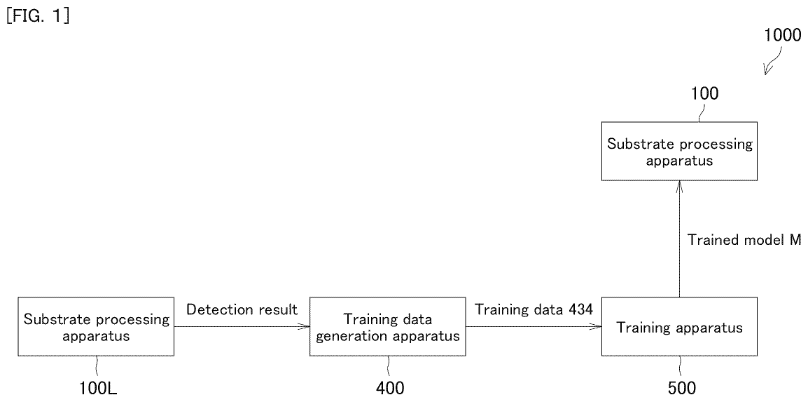

A substrate processing training system 1000 according to the first preferred embodiment of the present invention will be described with reference to FIGS. 1 to 14. FIG. 1 is a diagram illustrating the overall configuration of the substrate processing training system 1000 according to the first preferred embodiment.

As illustrated in FIG. 1, the substrate processing training system 1000 includes a substrate processing apparatus 100, a substrate processing apparatus 100L, a training data generation apparatus 400, and a training apparatus 500.

The substrate processing apparatus 100 processes a processing target substrate using a processing liquid. The substrate processing apparatus 100 is a single substrate processing type apparatus that processes processing target substrates one by one. Typically, a processing target substrate has a substantially disk shape.

The substrate processing apparatus 100L processes the training target substrate with a processing liquid. The configuration of the training target substrate is, for example, the same as the configuration of a processing target substrate. Typically, the training target substrate has a substantially disk shape. The substrate processing apparatus 100L is a single substrate processing type apparatus that processes training target substrates one by one. The configuration of the substrate processing apparatus 100L is substantially the same as the configuration of the substrate processing apparatus 100. The substrate processing apparatus 100L may be the same as the substrate processing apparatus 100. For example, the same substrate processing apparatus may process a training target substrate in the past and then process the processing target substrate. Alternatively, the substrate processing apparatus 100L may be another product having substantially the same configuration as the substrate processing apparatus 100.

In the following description of the present specification, the training target substrate is sometimes referred to as a “training target substrate WL,” and the processing target substrate is sometimes referred to as a “processing target substrate Wp.” In addition, when it is not necessary to distinguish and describe the training target substrate WL and the processing target substrate Wp, the training target substrate WL and the processing target substrate Wp may be referred to as a “substrate W”.

The substrate W is, for example, a semiconductor wafer, a liquid crystal display device substrate, a plasma display substrate, a field emission display (FED) substrate, an optical disk substrate, a magnetic disk substrate, a magneto-optical disk substrate, a photomask substrate, a ceramic substrate, or a solar cell substrate.

The substrate processing apparatus 100L acquires a first detection result and a second detection result to be described later by processing the training target substrate WL. The first detection result and the second detection result are input to the training data generation apparatus 400. For example, the first detection result and the second detection result may be input to the training data generation apparatus 400 by communication. Alternatively, the first detection result and the second detection result may be input to the training data generation apparatus 400 via a storage medium. The storage medium may be, for example, an optical disk such as a compact disc (CD) or a storage such as a universal serial bus (USB) memory. Alternatively, the user may input the first detection result and the second detection result by operating an input device such as a keyboard, a mouse, or a touch sensor.

The training data generation apparatus 400 generates training data 434 by associating the first detection result (the detection result obtained by a first training sensor 50L to be described later) with the second detection result (the detection result obtained by a second training sensor 60L to be described later). Specifically, the training data generation apparatus 400 associates the information indicating the first detection result detected by the first training sensor 50L with the information indicating the second detection result detected by the second training sensor 60L at substantially the same time.

The training apparatus 500 generates a trained model M by machine training based on the training data 434. Specifically, the training apparatus 500 generates the trained model M by inputting the training data 434 to a training program.

The substrate processing apparatus 100 inputs the detection result obtained by the first processing sensor 50 to the trained model M. As a result, at least one of the estimated wind speed and the estimated wind direction at a predetermined position (a second position during processing P1 to be described later) is output from the trained model M.

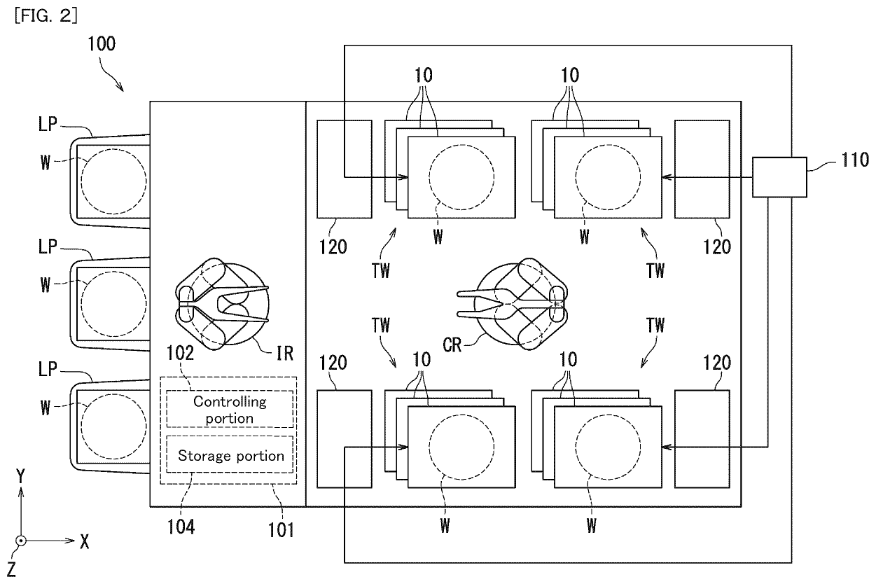

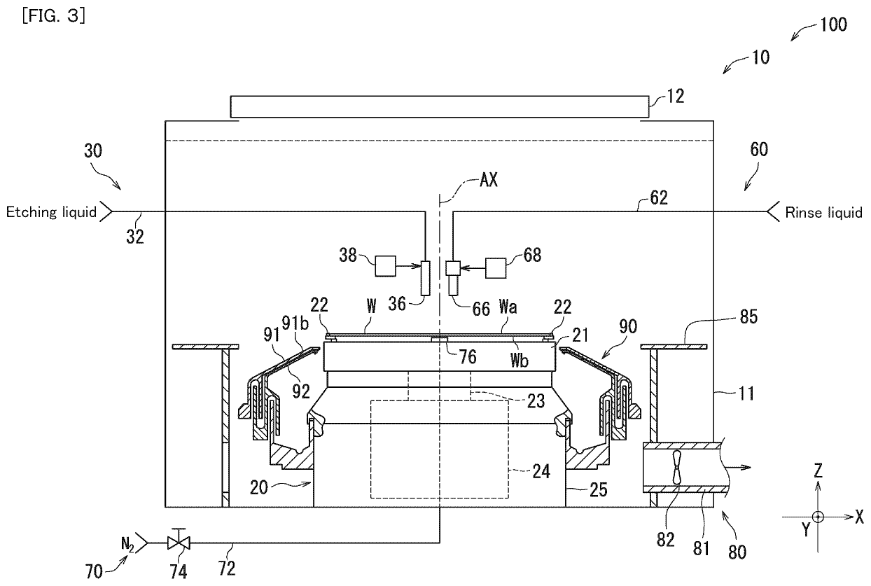

Hereinafter, the substrate processing training system 1000 will be further described with reference to FIGS. 2 to 14. First, the substrate processing apparatus 100 will be further described with reference to FIGS. 2 and 3. FIG. 2 is a schematic diagram of the substrate processing apparatus 100 according to the first preferred embodiment. Specifically, FIG. 2 is a schematic plan view of the substrate processing apparatus 100. In the first preferred embodiment, the substrate W is a semiconductor wafer. The substrate W has a substantially disk shape.

As illustrated in FIG. 2, the substrate processing apparatus 100 includes a plurality of processing units 10, a fluid cabinet 110, a plurality of fluid boxes 120, a plurality of load ports LP, an indexer robot IR, a center robot CR, and a controller 101.

Each of the load ports LP accommodates a plurality of substrates W in a stacked state. The indexer robot IR transports the substrates W between the load port LP and the center robot CR. The center robot CR transports the substrates W between the indexer robot IR and the processing unit 10. Each of the processing units 10 supplies a processing liquid to the substrate W and executes processing on the substrate W. The fluid cabinet 110 accommodates the processing liquid. The processing liquid includes, for example, a chemical liquid, a rinse liquid, and a removing liquid and/or a water-repellent agent. The fluid cabinet 110 accommodates the processing liquid. It is noted that, the fluid cabinet 110 may accommodate a gas.

The plurality of processing units 10 form a plurality of towers TW (four towers TW in FIG. 2) disposed to surround the center robot CR in plan view. Each tower TW includes a plurality of processing units 10 (three processing units 10 in FIG. 2) stacked vertically. The fluid boxes 120 correspond to a plurality of towers TW, respectively. A processing liquid in the fluid cabinet 110 is supplied to all of the processing units 10 included in the tower TW corresponding to the fluid box 120 through any one of the fluid boxes 120.

The controller 101 controls the operation of each portion of the substrate processing apparatus 100. For example, the controller 101 controls the load port LP, the indexer robot IR, and the center robot CR.

Subsequently, the processing unit 10 according to the first preferred embodiment will be described with reference to FIG. 3. FIG. 3 is a schematic diagram of the processing unit 10 according to the first preferred embodiment. Specifically, FIG. 3 is a schematic cross-sectional view of the processing unit 10.

As shown in FIG. 3, in the first preferred embodiment, the processing liquid contains, for example, an etching liquid, and the processing unit 10 executes etching processing. The substrate W is processed (etched) with an etching liquid. The etching liquid is a chemical liquid. Examples of the etching liquid include fluonitric acid (a mixed solution of hydrofluoric acid (HF) and nitric acid (HNO₃) ), hydrofluoric acid, buffered hydrofluoric acid (BHF), ammonium fluoride, HFEG (a mixed solution of hydrofluoric acid and ethylene glycol), phosphoric acid (H₃PO₄), SC1 (a mixed solution of ammonia and hydrogen peroxide water), SC2 (a mixed solution of hydrochloric acid and hydrogen peroxide water), SPM (a mixed solution of sulfuric acid and hydrogen peroxide water), and ammonia.

As illustrated in FIG. 3, the processing unit 10 includes a processing chamber 11, a blower unit 12, substrate holding portion 20, a chemical liquid supplying portion 30, and a rinse liquid supplying portion 60. The rinse liquid supplying portion 60 is an example of “cleaning liquid supplying portion” according to the present invention.

The processing chamber 11 has a substantially box shape with an internal space. The processing chamber 11 accommodates the substrate W. Here, the substrate processing apparatus 100 is a single substrate processing type that processes the substrates W one by one, and the processing chamber 11 accommodates the substrates W one by one. The substrate W is accommodated in the processing chamber 11 and processed in the processing chamber 11. At least part of each of the substrate holding portion 20, the chemical liquid supplying portion 30, and the rinse liquid supplying portion 60 is accommodated in the processing chamber 11.

The blower unit 12 is disposed on or above the processing chamber 11. For example, the blower unit 12 is placed on the top surface of the processing chamber 11. The blower unit 12 sends air into the processing chamber 11. The blower unit 12 includes, for example, a fan filter unit (FFU). A downflow (downward flow) is formed in the processing chamber 11 by the blower unit 12 and an exhaust device 80 to be described later.

The substrate holding portion 20 holds the substrate W. The substrate holding portion 20 directs an upper surface (front surface) Wa of the substrate W upwardly and horizontally holds the substrate W such as to direct a lower surface (rear surface) Wb of the substrate 3 downwardly in the vertical direction. Also, the substrate holding portion 20 rotates the substrate W in a state of holding the substrate W. For example, a laminated structure in which a recess is formed is provided on the upper surface Wa of the substrate W. The substrate holding portion 20 rotates the substrate W while holding the substrate W.

For example, the substrate holding portion 20 may be a gripping-type that clamps an end portion of the substrate W. Alternatively, the substrate holding portion 20 may have an arbitrary mechanism that holds the substrate W from the lower surface Wb. For example, the substrate holding portion 20 may be of a vacuum type. In this case, the substrate holding portion 20 horizontally holds the substrate W by suctioning, on an upper surface, a central portion of the lower surface Wb of the substrate W as the non-device-forming surface. Alternatively, the substrate holding portion 20 may be a combination of the gripping-type and the vacuum-type in which a plurality of chuck pins are brought into contact with a circumferential end surface of the substrate W.

For example, the substrate holding portion 20 includes a spin base 21, a chuck member 22, a shaft 23, a spin motor 24, and a housing 25. The chuck member 22 is provided on the spin base 21. The chuck member 22 chucks the substrate W. Typically, the spin base 21 includes a plurality of chuck members 22.

The shaft 23 extends in the vertical direction along a rotational axis AX. A spin base 21 is coupled to an upper end of the shaft 23. The substrate W is placed above the spin base 21.

The spin base 21 has a disk shape. The chuck member 22 horizontally supports the substrate W. The shaft 23 extends downward from a central portion of the spin base 21. The spin motor 24 gives a rotational force to the shaft 23. The spin motor 24 rotates the substrate W and the spin base 21 centering around the rotational axis AX by rotating the shaft 23 in the rotational direction. The housing 25 houses the shaft 23 and the spin motor 24.

The chemical liquid supplying portion 30 supplies a chemical liquid (in this case, an etching liquid) to the substrate W. Typically, chemical liquid supplying portion 30 supplies a chemical liquid to the upper surface Wa of the substrate W. At least one part of the chemical liquid supplying portion 30 is housed in the processing chamber 11.

The chemical liquid supplying portion 30 includes a piping 32 and a nozzle 36. The nozzle 36 discharges a chemical liquid to the upper surface Wa of the substrate W. The nozzle 36 is connected to the piping 32. A chemical liquid is supplied from a supply source to the piping 32.

The nozzle 36 may be configured such as to be movable with respect to the substrate W. The chemical liquid supplying portion 30 may further have a nozzle moving portion 38. The nozzle moving portion 38 may elevate and lower the nozzle 36, and may horizontally turn the nozzle 36 around the turning axis. The nozzle moving portion 38 elevates and lowers the nozzle 36. For example, the nozzle moving portion 38 includes a ball screw mechanism and an electric motor that gives a driving force to the ball screw mechanism. Also, the nozzle moving portion 38 horizontally turns the nozzle 36. For example, the nozzle moving portion 38 includes an electric motor.

The chemical liquid supplying portion 30 may supply a chemical liquid other than the etching liquid to the substrate W. In addition, the substrate processing apparatus 100 may include a processing liquid supplying portion that supplies a processing liquid other than the chemical liquid instead of the chemical liquid supplying portion 30.

The rinse liquid supplying portion 60 supplies a rinse liquid to the substrate W. Typically, the rinse liquid supplying portion 60 supplies a rinse liquid to the upper surface Wa of the substrate W. At least one part of the rinse liquid supplying portion 60 is housed in the processing chamber 11.

Deionized water (DIW), carbonated water, electrolyzed ion water, ozone water, aqueous hydrochloric acid solution of dilute concentration (for example, approximately 10 ppm to 100 ppm), or reduced water (hydrogen water) can be presented as an example of the rinse liquid. In the first preferred embodiment, the rinse liquid is deionized water (DIW).

The rinse liquid supplying portion 60 includes a piping 62 and a nozzle 66. The nozzle 66 discharges a rinse liquid to the upper surface Wa of the substrate W. The nozzle 66 is connected to the piping 62. The rinse liquid is supplied from the supply source to the piping 62.

The nozzle 66 may be configured such as to be movable with respect to the substrate W. The rinse liquid supplying portion 60 may further include a nozzle moving portion 68. The nozzle moving portion 68 may elevate and lower the nozzle 66 and may horizontally turn the nozzle 66 around the turning axis. The nozzle moving portion 68 may have the same configuration as the nozzle moving portion 38.

The processing unit 10 further includes an inert gas supplying portion 70. The kind of inert gas is not particularly limited, but is, for example, nitrogen gas. The inert gas supplying portion 70 includes a piping 72, a valve 74, and a nozzle 76.

The nozzle 76 discharges an inert gas to the lower surface Wb of the substrate W. For example, the nozzle 76 discharges an inert gas to the central portion of the substrate W. The nozzle 76 has a discharge port and discharges an inert gas from the discharge port. The nozzle 76 discharges an inert gas, for example, in the straight upward direction or the horizontal direction. The nozzle 76 is connected to the piping 72. The inert gas is supplied from a supply source to the piping 72. The valve 74 can adjust the supply amount of inert gas by adjusting the opening degree of the channel of the piping 72.

The processing unit 10 further includes the exhaust device 80. The exhaust device 80 includes an exhaust pipe 81 and an exhaust fan 82. The exhaust pipe 81 is disposed such as to penetrate a side wall of the processing chamber 11. The exhaust pipe 81 makes the inside and the outside of the processing chamber 11 communicate with each other. The exhaust fan 82 discharges the air in the processing chamber 11 to the outside of the processing chamber 11 via the exhaust pipe 81. The exhaust fan 82 can change the exhaust amount by changing the rotation speed. The exhaust fan 82 is disposed, for example, at the inlet of the exhaust pipe 81, the inside of the exhaust pipe 81, or the outlet of the exhaust pipe 81. In the first preferred embodiment, the exhaust fan 82 is disposed inside the exhaust pipe 81. In the first preferred embodiment, the rotation speed means the number of rotations per minute (rpm).

The processing unit 10 further includes a cup 90. The cup 90 collects a processing liquid scattered from the substrate W. The cup 90 is elevated and lowered. For example, the cup 90 rises vertically upward to a side of the substrate W over a period in which the chemical liquid supplying portion 30 and/or the rinse liquid supplying portion 60 supply the chemical liquid and/or the rinse liquid to the substrate W. In this case, the cup 90 collects the chemical liquid and/or the rinse liquid scattered from the substrate W by the rotation of the substrate W. In addition, the cup 90 descends vertically downward from a side of the substrate W when the period in which the chemical liquid supplying portion 30 and/or the rinse liquid supplying portion 60 supply the chemical liquid and/or the rinse liquid to the substrate W ends. In the first preferred embodiment, the cup 90 includes a cup 91 disposed on the outermost periphery and a cup 92 disposed inside the cup 91.

The substrate processing apparatus 100 of the first preferred embodiment is suitably used for manufacturing a semiconductor element provided with a semiconductor. Typically, in a semiconductor element, a conductive layer and an insulating layer are laminated on a base material. The substrate processing apparatus 100 is suitably used for cleaning and/or processing (for example, etching, characteristic change, and the like) of the conductive layer and/or the insulating layer at the time of manufacturing the semiconductor element.

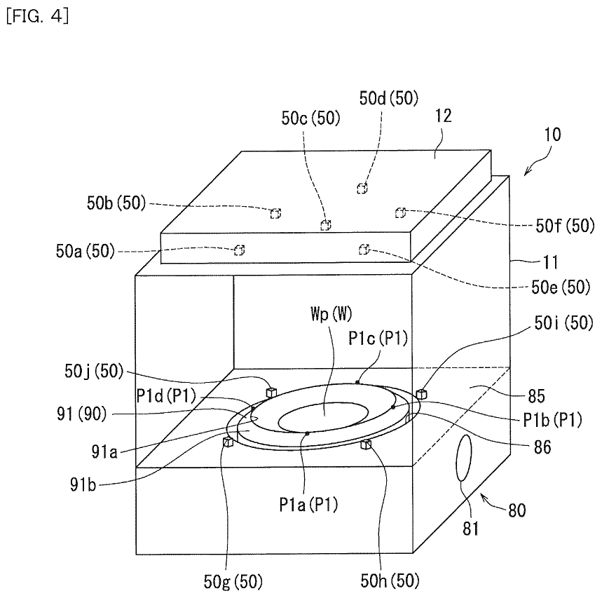

Next, the processing unit 10 of the substrate processing apparatus 100 according to the first preferred embodiment will be further described with reference to FIG. 4. FIG. 4 is a perspective view schematically illustrating the processing unit 10 of the substrate processing apparatus 100 according to the first preferred embodiment.

As illustrated in FIG. 4, the processing unit 10 of the substrate processing apparatus 100 includes a first processing sensor 50. The first processing sensor 50 is disposed in or around the processing chamber 11. The first processing sensor 50 detects at least one of a wind speed and a wind direction at a first position during processing in or around the processing chamber 11. In the first preferred embodiment, the first processing sensor 50 is disposed in the processing chamber 11. In the first preferred embodiment, the first processing sensor 50 detects both a wind speed and a wind direction at the first position during processing in the processing chamber 11. The first processing sensor 50 outputs a detection result to a first controlling portion 102.

The detection interval of the first processing sensor 50 is not particularly limited but ranges, for example, from 0.1 sec to 10 sec inclusive. In the first preferred embodiment, the first processing sensor 50 detects about every 1 sec.

The first processing sensor 50 is not particularly limited but can detect, for example, at least one of a three-dimensional wind speed and a three-dimensional wind direction. In the first preferred embodiment, the first processing sensor 50 can detect both a three-dimensional wind speed and a three-dimensional wind direction. The first processing sensor 50 is, for example, a polyimide substrate having a semiconductor chip mounted thereon that detects a wind speed and a wind direction.

The number of first processing sensors 50 is not particularly limited but is preferably plural. In the first preferred embodiment, for example, 10 first processing sensors 50 are provided. That is, the processing unit 10 includes the first processing sensors 50a to 50j. The first processing sensors 50a to 50j are disposed at predetermined positions in the processing chamber 11. The positions where the first processing sensors 50a to 50j are disposed are an example of the “first position during processing” according to the present invention.

Specifically, the processing unit 10 includes a partition plate 85. The partition plate 85 vertically partitions a space around the cup 90 in the processing chamber 11. The first processing sensors 50a to 50f are disposed, for example, below the blower unit 12. The first processing sensors 50a to 50f are disposed separately from each other in the horizontal direction. The first processing sensors 50 are disposed in a staggered manner, for example. The first processing sensors 50a to 50f are disposed on the ceiling of the processing chamber 11 but may be disposed between the ceiling of the processing chamber 11 and the lower surface of the blower unit 12.

The first processing sensors 50g to 50j are disposed on, for example, the partition plate 85. The first processing sensors 50g to 50j are disposed outside an opening edge portion 86 of the partition plate 85. The opening edge portion 86 is formed in a circular shape surrounding the periphery of the cup 90. The first processing sensors 50g to 50j are disposed at substantially equal angular intervals in the circumferential direction around the cup 90.

The processing unit 10 has the second position during processing P1. The number of second positions during processing P1 is not particularly limited but is preferably plural. In the first preferred embodiment, the four second positions during processing P1 are provided. That is, the processing unit 10 has second positions during processing P1a to P1d.

The second positions P1a to P1d during processing are, for example, positions around the substrate W or the substrate holding portion 20. The second positions P1a to P1d during processing are, for example, positions where the processing liquid discharged from the substrate W can reach. In the first preferred embodiment, the second positions P1a to P1d during processing are positions on the cup 90. The second positions P1a to P1d during processing are, for example, positions on the outermost cup 91 of the cup 90. In addition, the second positions P1a to P1d during processing are positions outside the opening edge portion 91a of the outermost cup 91. The opening edge portion 91a is formed in a circular shape surrounding the periphery of the substrate W. The second positions P1a to P1d during processing are positions on an inclined surface 91b of the outermost cup 91 which is inclined downward from the highest position of the outermost peripheral cup 91 toward the radial outside.

The second positions P1a to P1d during processing are disposed at substantially equal angular intervals in the circumferential direction around the substrate W. In the first preferred embodiment, the first processing sensors 50g to 50j and the second positions P1a to P1d during processing are alternately disposed in the circumferential direction around the substrate W. In the first preferred embodiment, the first processing sensors 50g to 50j and the second positions P1a to P1d during processing are disposed at a pitch of about 45° in the circumferential direction around the substrate W.

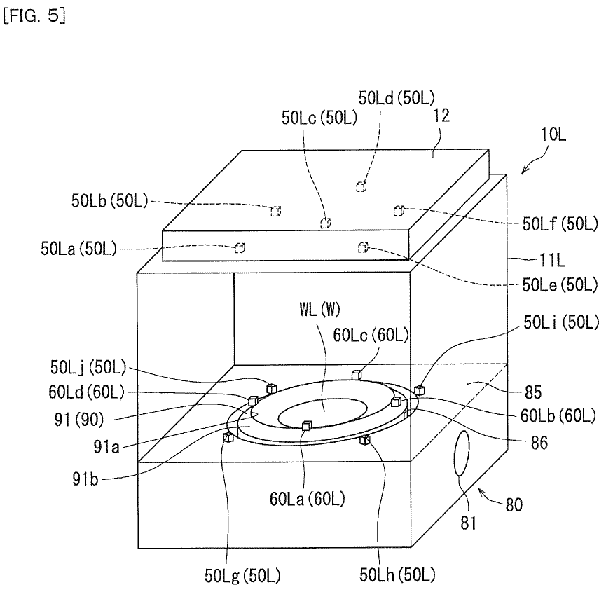

Next, the substrate processing apparatus 100L according to the first preferred embodiment will be further described with reference to FIG. 5. FIG. 5 is a perspective view schematically illustrating the processing unit 10L of the substrate processing apparatus 100L according to the first preferred embodiment. Since the substrate processing apparatus 100L has substantially the same structure as the substrate processing apparatus 100 described with reference to FIGS. 2 to 4, different configurations will be mainly described. The substrate processing apparatus 100L includes the processing unit 10L.

As illustrated in FIG. 5, the processing unit 10L of the substrate processing apparatus 100L includes a training chamber 11L. The training chamber 11L has the same structure as the processing chamber 11 of the processing unit 10.

The processing unit 10L includes the first training sensor 50L. The first training sensor 50L has the same structure as the first processing sensor 50 of the processing unit 10. The first training sensor 50L is disposed in or around the training chamber 11L. The first training sensor 50L detects at least one of a wind speed and a wind direction at the first position during training in or around the training chamber 11L. In the first preferred embodiment, the first training sensor 50L is disposed in the training chamber 11L. In the first preferred embodiment, the first training sensor 50L detects both a wind speed and a wind direction at the first position during training in the training chamber 11L. The first training sensor 50L outputs a detection result to a second controlling portion 102L. The first position during training in the training chamber 11L is substantially the same as the first position during processing in the processing chamber 11.

The number of first training sensors 50L is the same as the number of first processing sensors 50. In the first preferred embodiment, for example, 10 first training sensors 50L are provided. That is, the processing unit 10L includes first training sensors 50La to 50Lj. The first training sensors 50La to 50Lj are disposed at positions corresponding to the first processing sensors 50a to 50j. The positions where the first training sensors 50La to 50Lj are disposed are an example of the “first position during training” of the present invention.

Here, in the first preferred embodiment, the processing unit 10L includes the second training sensor 60L which is different from the processing unit 10. The second training sensor 60L has, for example, the same structure as the first processing sensor 50 and the first training sensor 50L.

The second training sensor 60L is disposed in the training chamber 11L. The second training sensor 60L detects at least one of a wind speed and a wind direction at the second position during training in the training chamber 11L. In the first preferred embodiment, the second training sensor 60L detects both a wind speed and a wind direction at the second position during training in the training chamber 11L. The second training sensor 60L outputs the detection result to the second controlling portion 102L. The second position during training in the training chamber 11L is substantially the same as the second position during processing P1 (see FIG. 4) in the processing chamber 11.

Specifically, the number of second training sensors 60L is the same as the number of second positions during processing P1. In the first preferred embodiment, four second training sensors 60L are provided. That is, the processing unit 10L includes the second training sensors 60La to 60Ld. The second training sensors 60La to 60Ld are disposed at the second positions during training.

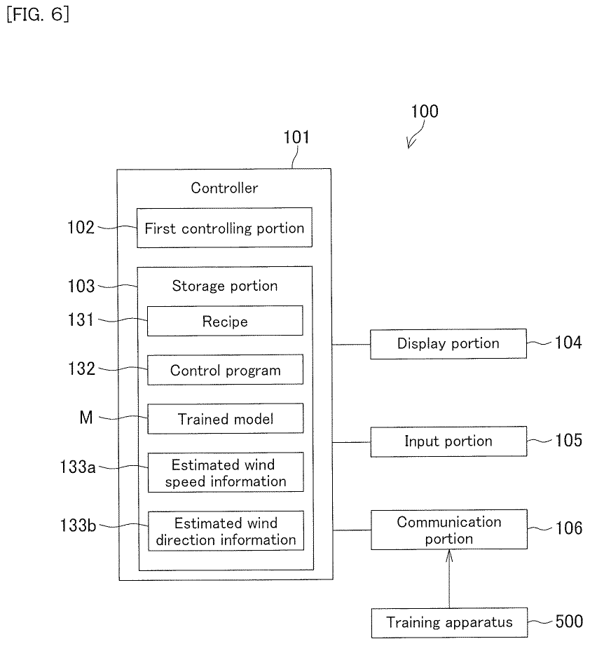

Next, the substrate processing apparatus 100 will be described further with reference to FIG. 6. FIG. 6 is a block diagram showing part of the substrate processing apparatus 100 according to the first preferred embodiment. As illustrated in FIG. 6, the controller 101 includes a first controlling portion 102 and a storage portion 103. The substrate processing apparatus 100 further includes a display portion 104, an input portion 105, and a communication portion 106. The first controlling portion 102 is an example of a “controlling portion” according to the present invention.

The first controlling portion 102 includes a processor. The first controlling portion 102 includes, for example, a central processing unit (CPU) or a micro processing unit (MPU). Alternatively, the first controlling portion 102 may have a general-purpose computing unit or a specialized computing unit. The first controlling portion 102 may further include a neural network processing unit (NPU).

The storage portion 103 stores data and a computer program. The storage portion 103 has a main storage. The main storage is, for example, a semiconductor memory. The storage portion 103 may further include an auxiliary storage. The auxiliary storage is, for example, a semiconductor memory and/or a hard disk drive. The storage portion 103 may include a removable medium. The first controlling portion 102 controls the operation of each portion of the substrate processing apparatus 100 on the basis of data and a computer program stored in the storage portion 103.

Specifically, the storage portion 103 stores a recipe 131 and a control program 132. The recipe 131 defines processing details and processing procedures of the substrate W. In addition, the recipe 131 indicates processing conditions and various set values. In the first preferred embodiment, the processing conditions include, for example, the rotation speed of the blower fan built in the blower unit 12, the rotation speed of the exhaust fan 82, the rotation speed of the substrate W, the opening degree of the valve 74 provided in the piping 72 for supplying nitrogen gas to the nozzle 76, and the like.

The first controlling portion 102 controls the operation of each portion of the substrate processing apparatus 100 on the basis of the recipe 131 and the control program 132. In the first preferred embodiment, the first controlling portion 102 causes the display portion 104 to display an image based on the estimated wind speed and the estimated wind direction to be described later.

The storage portion 103 stores the trained model M. The trained model M is generated by the training apparatus 500 (see FIG. 2) and then transmitted to and stored in the substrate processing apparatus 100.

The trained model M is a model for estimating at least one of a wind speed and a wind direction at the second position during processing P1 based on at least one of a wind speed and a wind direction at the first position during processing in the processing chamber 11. Since the processing liquid discharged from the substrate W scatters at the second position during processing P1, the sensor deteriorates. Therefore, a sensor that detects a wind speed, a wind direction, and the like cannot be disposed at the second position during processing P1. Therefore, in the first preferred embodiment, information indicating a wind speed and a wind direction at the first position during training and a wind speed and a wind direction at the second position during training is acquired using the processing unit 10L having the same structure as the processing unit 10. Then, a model (the trained model M) for estimating at least one of a wind speed and a wind direction at the second position during processing P1 is generated using the acquired information.

Specifically, the trained model M outputs at least one of the estimated wind speed and the estimated wind direction at the second position during processing P1 based on the detection result obtained by the first processing sensor 50 as the input data. In the first preferred embodiment, the trained model M outputs both the estimated wind speed and the estimated wind direction at the second position during processing P1 based on the detection result obtained by the first processing sensor 50 which is the input data.

The storage portion 103 stores estimated wind speed information 133a and estimated wind direction information 133b indicating the estimated wind speed and the estimated wind direction at the second position during processing P1.

A method of generating the trained model M will be described later.

The display portion 104 displays various types of information. In the first preferred embodiment, the display portion 104 displays, for example, various setting screens (input screens). In addition, the display portion 104 displays, for example, an image based on the estimated wind speed and the estimated wind direction to be described later. Furthermore, the display portion 104 includes, for example, a liquid crystal display or an organic electroluminescence (EL) display.

The input portion 105 receives an input from the user. For example, the input portion 105 receives the execution of processing on the substrate W, the stop of processing on the substrate W, the change of processing conditions and various set values, and the like. Furthermore, the input portion 105 includes, for example, a touch panel and a pointing device. The touch panel is disposed on, for example, the display surface of the display portion 104. The input portion 105 and the display portion 104 constitute, for example, a graphical user interface.

The communication portion 106 is connected to a network and communicates with an external device. The network includes, for example, the Internet, a local area network (LAN), a public telephone network, and a short-range wireless network. The communication portion 106 is a communication device, for example, a network interface controller. In the first preferred embodiment, the communication portion 106 executes communication with the training apparatus 500. The communication portion 106 receives the trained model M from the training apparatus 500. The first controlling portion 102 stores the trained model M received by the communication portion 106 in the storage portion 103.

The substrate processing apparatus 100 has been described above with reference to FIGS. 1 to 6. In the first preferred embodiment, as described above, the substrate processing apparatus 100 includes the first processing sensor 50 that detects at least one of a wind speed and a wind direction at the first position during processing and the first controlling portion 102 that inputs the detection result obtained by the first processing sensor 50 to the trained model M and acquires at least one of the estimated wind speed and the estimated wind direction at the second position during processing P1 of the processing chamber 11. Therefore, at least one of the wind speed and the wind direction at the second position during processing P1 can be estimated based on at least one of the wind speed and the wind direction at the first position during processing at the time of substrate processing. That is, at least one of the wind speed and the wind direction at the position where the sensor cannot be disposed (the second position during processing P1) can be estimated based on at least one of the wind speed and the wind direction at another position (the first position during processing).

In addition, since the substrate processing apparatus 100 calculates at least one of the wind speed and the wind direction only for a specific position (the second position during processing P1) of the processing chamber 11, the time for estimation can be shortened as compared with, for example, a case where at least one of the wind speed and the wind direction is calculated for the entire space in the chamber. As a result, for example, at least one of the wind speed and the wind direction at the second position during processing P1 can be monitored while substrate processing is executed.

As described above, the first controlling portion 102 inputs the detection result obtained by the first processing sensor 50 at the time of cleaning to the trained model M and acquires at least one of the estimated wind speed and the estimated wind direction at the time of cleaning. At the time of cleaning, for example, the cleanliness and/or the dryness may be affected by the wind speed or the wind direction around the substrate holding portion 20. That is, cleanliness and/or dryness sometimes decreases. Therefore, as described above, by acquiring at least one of the estimated wind speed and the estimated wind direction at the second position during processing P1 at the time of cleaning, for example, at least one of the wind speed and the wind direction around the substrate W can be estimated, so that adverse effects on the cleanliness and/or the dryness can be suppressed.

As described above, the second position during processing P1 is a position on the cup 90. Therefore, by estimating at least one of the wind speed and the wind direction at the second position during processing P1, at least one of the wind speed and the wind direction around the substrate W can be easily estimated.

As described above, the display portion 104 displays at least one of the estimated wind speed and the estimated wind direction. Therefore, the user can check at least one of the estimated wind speed and the estimated wind direction at the second position during processing P1 only by looking at the display portion 104.

As described above, the processing condition that allows the user to change at least one of the estimated wind speed and the estimated wind direction is input to the input portion 105. Therefore, for example, the user who looks at the display portion 104 can change the processing condition so that the estimated wind speed and the estimated wind direction at the second position during processing P1 fall within a predetermined range. The user may stop the processing.

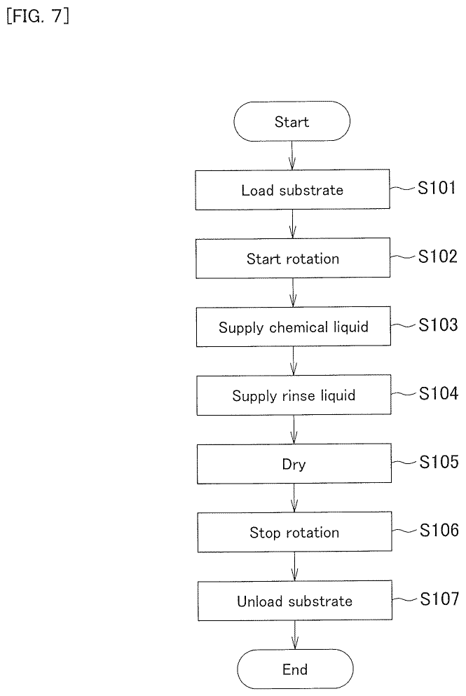

Next, a substrate processing method by the substrate processing apparatus 100 will be described with reference to FIG. 7. FIG. 7 is a flowchart showing the substrate processing method by the substrate processing apparatus 100 according to the first preferred embodiment. The substrate processing method by the substrate processing apparatus 100 includes at least steps S104 and S105. In the first preferred embodiment, the substrate processing method includes steps S101 to S107. Steps S101 to S107 are executed by the first controlling portion 102.

As illustrated in FIG. 7, in step S101, the processing target substrate Wp is loaded into the processing chamber 11. Under the control of the first controlling portion 102, the center robot CR loads the processing target substrate into the processing chamber 11, and the substrate holding portion 20 holds the loaded processing target substrate Wp.

Next, in step S102, the rotation of the processing target substrate Wp is started. Under the control of the first controlling portion 102, the substrate holding portion 20 starts rotation of the processing target substrate Wp while holding the processing target substrate Wp.

Next, in step S103, the chemical liquid is supplied to the processing target substrate Wp to process the processing target substrate Wp. Under the control of the first controlling portion 102, the chemical liquid supplying portion 30 supplies the chemical liquid from the nozzle 36 to the processing target substrate Wp rotated by the substrate holding portion 20. Then, the first controlling portion 102 stops the supply of the chemical liquid when a predetermined time has elapsed from the start of the supply of the chemical liquid.

Next, in step S104, a rinse liquid is supplied to the processing target substrate Wp to rinse the processing target substrate Wp. Under the control of the first controlling portion 102, the rinse liquid supplying portion 60 supplies the rinse liquid from the nozzle 66 to the processing target substrate Wp. For example, the rinse liquid supplying portion 60 supplies DIW as the rinse liquid. Then, the first controlling portion 102 stops the supply of the rinse liquid when a predetermined time has elapsed from the start of the supply of the rinse liquid.

Next, in step S105, the processing target substrate Wp is dried. Under the control of the first controlling portion 102, the substrate holding portion 20 increases the rotation speed of the processing target substrate Wp and blows off the rinse liquid on the processing target substrate Wp by a centrifugal force.

Next, in step S106, the rotation of the processing target substrate Wp is stopped. Under the control of the first controlling portion 102, the substrate holding portion 20 stops the rotation of the processing target substrate Wp.

Next, in step S107, the processing target substrate Wp is taken out from the processing unit 10. Under the control of the first controlling portion 102, the substrate holding portion 20 releases the holding of the processing target substrate Wp, and the center robot CR takes out the processing target substrate Wp from the processing chamber 11. Thereafter, the processing target substrate Wp is transferred to the outside of the substrate processing apparatus 100 via the indexer robot IR.

As described above, the processing on the processing target substrate Wp ends.

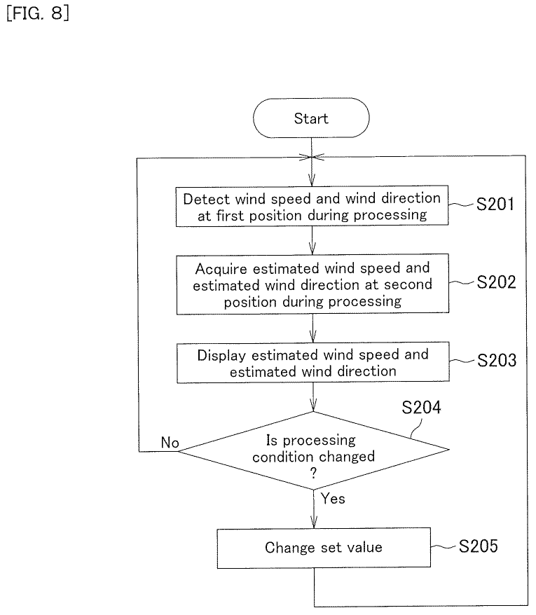

Next, a method of estimating a wind speed and a wind direction at the second position during processing P1 by the substrate processing apparatus 100 will be described with reference to FIG. 8. FIG. 8 is a flowchart illustrating a method of estimating the wind speed and the wind direction at the second position during processing P1 by the substrate processing apparatus 100. The method of estimating the wind speed and the wind direction at the second position during processing P1 by the substrate processing apparatus 100 includes at least steps S201 and S202. In the first preferred embodiment, the estimation method by the substrate processing apparatus 100 includes steps S201 to S205. Steps S201 to S205 are executed by the first controlling portion 102.

The method of estimating the wind speed and the wind direction at the second position during processing P1 by the substrate processing apparatus 100 is executed in parallel with at least steps S104 and S105 illustrated in FIG. 7. In the first preferred embodiment, the estimation method by the substrate processing apparatus 100 is executed in parallel with steps S102 to S106 described above.

As illustrated in FIG. 8, in step S201, at least one of a wind speed and a wind direction at the first position during processing is detected. In the first preferred embodiment, both the wind speed and the wind direction at the first position during processing are detected. Specifically, the first processing sensor 50 detects the wind speed and the wind direction and transmits a detection signal indicating a detection result to the first controlling portion 102. The first controlling portion 102 receives a detection signal from the first processing sensor 50. In the first preferred embodiment, as described above, the first processing sensor 50 detects the detection signal about every 1 sec, and the first controlling portion 102 receives the detection signal about every 1 sec.

Next, in step S202, at least one of the estimated wind speed and the estimated wind direction at the second position during processing P1 is acquired. In the first preferred embodiment, both the estimated wind speed and the estimated wind direction at the second position during processing P1 are acquired. Specifically, the first controlling portion 102 inputs the detection result obtained by the first processing sensor 50 to the trained model M and acquires the estimated wind speed and the estimated wind direction at the second position during processing P1. In the first preferred embodiment, the estimated wind speed and the estimated wind direction will be output by the time 0.1 sec or more and 0.5 sec or less elapse after the first controlling portion 102 inputs the detection result obtained by the first processing sensor 50 to the trained model M. Therefore, it is possible to cause the display portion 104 to display an image based on the estimated wind speed and the estimated wind direction by the time 0.1 sec or more and 0.5 sec or less elapse after the wind speed and the wind direction at the second position during processing P1 change. That is, the wind speed and the wind direction at the second position during processing P1 can be monitored.

Next, in step S203, at least one of the estimated wind speed and the estimated wind direction is displayed. In the first preferred embodiment, both the estimated wind speed and the estimated wind direction are displayed. Specifically, the first controlling portion 102 causes the display portion 104 to display the image based on the acquired estimated wind speed and estimated wind direction. Thereby, the display portion 104 displays the image based on the estimated wind speed and the estimated wind direction at the second position during processing P1.

Next, in step S204, the first controlling portion 102 determines whether or not the processing condition has been changed. Specifically, the user checks the estimated wind speed and the estimated wind direction displayed on the display portion 104.

Then, when the estimated wind speed and the estimated wind direction displayed on the display portion 104 deviate from the estimated wind speed and the estimated wind direction normally displayed at the time of cleaning or deviate from a predetermined wind speed range and/or a predetermined wind direction range, the user operates the input portion 105 to change the processing condition. At this time, the user changes the processing condition that can change at least one of the estimated wind speed and the estimated wind direction. The user changes, for example, at least one of the rotation speed of the blower fan built in the blower unit 12, the rotation speed of the exhaust fan 82, and the rotation speed of the processing target substrate Wp. In this case, the first controlling portion 102 determines that the processing condition has been changed. Thereafter, the process proceeds to step S205.

On the other hand, when the estimated wind speed and the estimated wind direction displayed on the display portion 104 do not deviate from the estimated wind speed and the estimated wind direction normally displayed at the time of cleaning, or when the estimated wind speed and the estimated wind direction are in a predetermined wind speed range and a predetermined wind direction range, the user does not operate the input portion 4. That is, the user does not change the processing condition. In this case, the first controlling portion 102 determines that the processing condition has not been changed. Thereafter, the process returns to step S201.

Next, in step S205, various set values are changed. Specifically, the first controlling portion 102 changes the set value of the rotation speed of the blower fan, the rotation speed of the exhaust fan 82, or the rotation speed of the processing target substrate Wp. Thereby, the estimated wind speed and the estimated wind direction at the second position during processing P1 change. The estimated wind speed and the estimated wind direction at the second position during processing P1 become or approach, for example, the estimated wind speed and the estimated wind direction normally displayed at the time of cleaning. Thereafter, the process returns to step S201.

In the estimation method by the substrate processing apparatus 100, steps S201 to S205 are repeated, and when the substrate processing method illustrated in FIG. 7 proceeds to step S107, the processing ends.

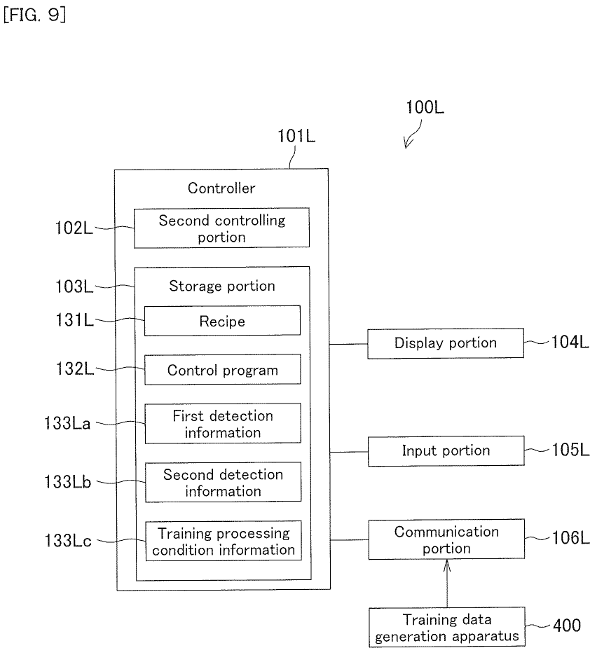

Next, the substrate processing apparatus 100 will be described further with reference to FIG. 9. FIG. 9 is a block diagram showing part of the substrate processing apparatus 100L according to the first preferred embodiment. As illustrated in FIG. 9, the substrate processing apparatus 100L includes a controller 101L which is different from the substrate processing apparatus 100. The controller 101L includes a second controlling portion 102L and a storage portion 103L. The substrate processing apparatus 100L further includes a display portion 104L, an input portion 105L, and a communication portion 106L.

The second controlling portion 102L includes a processor. The second controlling portion 102L includes, for example, a CPU or an MPU. Alternatively, the second controlling portion 102L may have a general-purpose computing unit or a specialized computing unit. The second controlling portion 102L may further include an NPU.

The storage portion 103L stores data and a computer program. The storage portion 103L has a main storage. The main storage is, for example, a semiconductor memory. The storage portion 103L may further include an auxiliary storage. The auxiliary storage is, for example, a semiconductor memory and/or a hard disk drive. The storage portion 103L may include a removable medium. The second controlling portion 102L controls the operation of each portion of the substrate processing apparatus 100 on the basis of the data and the computer program stored in the storage portion 103L.

Specifically, the storage portion 103L stores a recipe 131L and a control program 132L. The recipe 131L defines processing contents and processing procedures of the training target substrate WL. In addition, the recipe 131L indicates processing conditions and various set values. In the first preferred embodiment, the processing conditions include, for example, the rotation speed of the blower fan built in the blower unit 12, the rotation speed of the exhaust fan 82, the rotation speed of the training target substrate WL, the opening degree of the valve 74 provided in the piping 72 for supplying nitrogen gas to the nozzle 76, and the like. The recipe 131L may be the same as the recipe 131. The control program 132L may be the same as the control program 132.

The second controlling portion 102L controls the operation of each portion of the substrate processing apparatus 100L based on the recipe 131L and the control program 132L.

The second controlling portion 102L transmits the first detection result obtained by detecting at least one of the wind speed and the wind direction at the first position during training to the training data generation apparatus 400. Specifically, the second controlling portion 102L transmits first detection information 133La indicating the first detection result detected by the first training sensor 50L to the training data generation apparatus 400.

In addition, the second controlling portion 102L transmits the second detection result obtained by detecting at least one of the wind speed and the wind direction at the second position during training to the training data generation apparatus 400. Specifically, the second controlling portion 102L transmits second detection information 133Lb indicating the second detection result detected by the second training sensor 60L to the training data generation apparatus 400.

In addition, in the first preferred embodiment, the second controlling portion 102L also transmits processing conditions during training to the training data generation apparatus 400.

The storage portion 103L stores first detection information 133La indicating a first detection result, second detection information 133Lb indicating a second detection result, and training processing condition information 133Lc indicating processing conditions (to be sometimes referred to as a training processing condition hereinafter) during training.

The display portion 104L displays various items of information. In the first preferred embodiment, the display portion 104L displays, for example, various setting screens (input screens). Furthermore, the display portion 104L may display, for example, the image based on the first detection result and the second detection result. Furthermore, the display portion 104L includes, for example, a liquid crystal display or an organic EL display.

The input portion 105L receives an input from the user. For example, the input portion 105L receives the execution of processing on the training target substrate WL, the stop of processing on the training target substrate WL, the change of processing conditions and various set values, and the like. Furthermore, the input portion 105L includes, for example, a touch panel and a pointing device. The touch panel is disposed, for example, on the display surface of the display portion 104L. The input portion 105L and the display portion 104L constitute, for example, a graphical user interface.

The communication portion 106L is connected to a network and communicates with an external device. The network includes, for example, the Internet, a local area network (LAN), a public telephone network, and a short-range wireless network. The communication portion 106L is a communication device, for example, a network interface controller. In the first preferred embodiment, the communication portion 106L executes communication with the training data generation apparatus 400. The communication portion 106L transmits the first detection result, the second detection result, and the like to the training data generation apparatus 400.

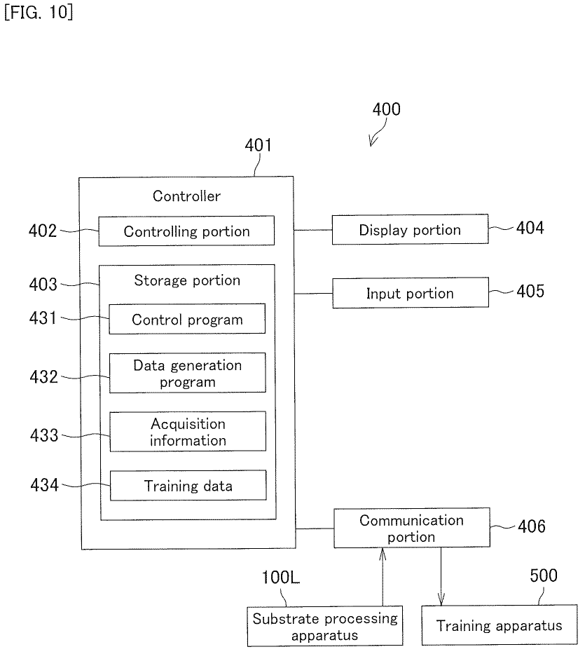

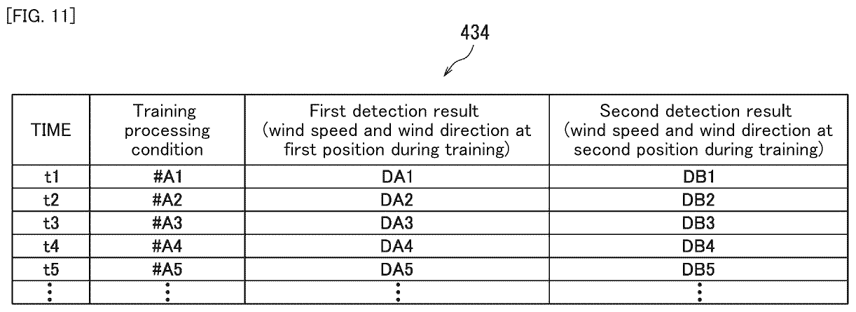

Next, the training data generation apparatus 400 will be further described with reference to FIGS. 10 and 11. FIG. 10 is a block diagram illustrating the training data generation apparatus 400. FIG. 11 is a diagram illustrating an example of the training data 434 generated by the training data generation apparatus 400.

As illustrated in FIG. 10, the training data generation apparatus 400 includes a controller 401. The controller 401 includes a controlling portion 402 and a storage portion 403.

The controlling portion 402 includes a processor. The controlling portion 402 includes, for example, a CPU or an MPU. Alternatively, the controlling portion 402 may include a general-purpose computing unit. The controlling portion 402 may further include an NPU.

The storage portion 403 stores the control program 431 and data. The control program 431 is a computer program. The storage portion 403 has a main storage. The storage portion 403 may further include an auxiliary storage. The storage portion 403 may include a removable medium. The controlling portion 402 executes various processes based on the control program 431 and data stored in the storage portion 403.

The storage portion 403 further stores a data generation program 432. The controlling portion 402 stores the first detection result, the second detection result, and the training processing condition (to be sometimes referred to as acquisition information 433 hereinafter) acquired from the substrate processing apparatus 100L in the storage portion 403.

The data generation program 432 is a program for generating training data by associating the first detection result with the second detection result. In the first preferred embodiment, the data generation program 432 is a program for generating training data 434 by associating the first detection result, the second detection result, and the training processing condition.

The controlling portion 402 generates the training data 434 by associating the first detection result with the second detection result and stores the training data in the storage portion 403. In the first preferred embodiment, the controlling portion 402 generates the training data 434 by associating the first detection result, the second detection result, and the training processing condition with each other and stores the training data in the storage portion 403. In the first preferred embodiment, as illustrated in FIG. 11, in the training data 434, the first detection result (DA1, DA2, . . . ) , the second detection result (DB1, DB2, . . . ) , and the training processing condition (#A1, #A2, . . . ) are generated as time series data.

As illustrated in FIG. 10, the training data generation apparatus 400 further includes a display portion 404, an input portion 405, and a communication portion 406.

The display portion 404 displays various screens and various types of information. The display portion 404 is, for example, a liquid crystal display or an organic EL display. The display portion 404 may display an input screen for inputting various data to the controlling portion 402.

The input portion 405 receives an input from the user and outputs various types of information to the controlling portion 402. The input portion 405 includes, for example, a touch panel and a pointing device. The input portion 405 may receive an input of an instruction to generate the training data 434.

The communication portion 406 is connected to a network and communicates with an external device. The network includes, for example, the Internet, a LAN, a public telephone network, and a short-range wireless network. The communication portion 406 is a communication device, for example, a network interface controller. In the first preferred embodiment, the communication portion 406 executes communication with the substrate processing apparatus 100L and the training apparatus 500. The communication portion 406 receives the first detection result, the second detection result, and the like from the substrate processing apparatus 100L. Furthermore, the communication portion 406 transmits the training data 434 to the training apparatus 500.

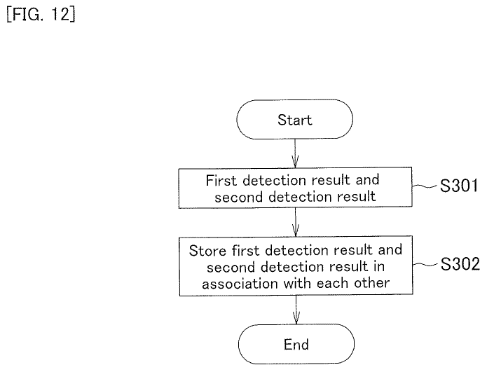

Next, a method of generating the training data 434 according to the first preferred embodiment will be described with reference to FIGS. 10 to 12. FIG. 12 is a flowchart illustrating a method of generating the training data 434 according to the first preferred embodiment. The method of generating the training data 434 includes steps S301 and S302. Steps S301 and S302 are executed by the controlling portion 402. Step S301 is an example of “a step of acquiring a first detection result” and “a step of acquiring a second detection result” according to the present invention. Further, step S302 is an example of “a step of storing the first detection result and the second detection result in association with each other as training data” according to the present invention.

As illustrated in FIG. 12, in step S301, the training data generation apparatus 400 (the controlling portion 402) acquires the first detection result and the second detection result. Typically, the controlling portion 402 acquires the first detection result and the second detection result from the substrate processing apparatus 100L. In the first preferred embodiment, the controlling portion 402 acquires the first detection result, the second detection result, and the training processing condition. The storage portion 403 stores the acquired acquisition information 433.

In the first preferred embodiment, the controlling portion 402 acquires the first detection result, the second detection result, and the training processing condition in one step (step S301) but may acquire the first detection result, the second detection result, and the training processing condition in separate steps.

In step S302, the controlling portion 402 stores the first detection result and the second detection result in association with each other in the storage portion 403 as training data. In the first preferred embodiment, the controlling portion 402 stores the first detection result, the second detection result, and the training processing condition in association with each other in the storage portion 403 as training data. Specifically, the controlling portion 402 generates the training data 434 by associating the first detection result, the second detection result, and the training processing condition with each other and stores the training data in the storage portion 403.

As described above, the generation of the training data 434 ends.

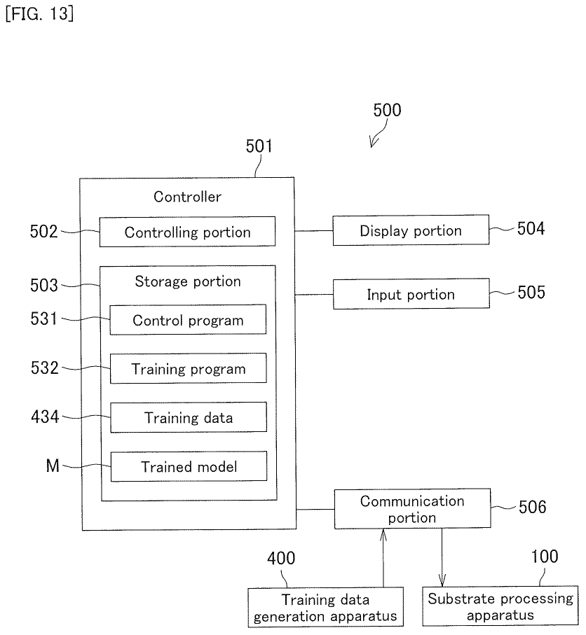

Next, the training apparatus 500 will be further described with reference to FIG. 13. FIG. 13 is a block diagram showing the training apparatus 500. As illustrated in FIG. 13, the training apparatus 500 includes a controller 501. The controller 501 includes a controlling portion 502 and a storage portion 503. The controlling portion 502 is an example of a “training portion” according to the present invention.

The controlling portion 502 includes a processor. The controlling portion 502 includes, for example, a CPU or an MPU. Alternatively, the controlling portion 502 may include a general-purpose computing unit. The controlling portion 502 may further include an NPU.

The storage portion 503 stores the control program 531 and data. The control program 531 is a computer program. The storage portion 503 has a main storage. The storage portion 503 may further include an auxiliary storage. The storage portion 503 may include a removable medium. The controlling portion 502 executes various processes based on the control program 531 and data stored in the storage portion 503.

The storage portion 503 further stores a training program 532. The controlling portion 502 stores the training data 434 acquired from the training data generation apparatus 400 in the storage portion 503.

The training program 532 is a program for finding a certain rule from the training data 434 and executing a machine training algorithm for generating the trained model M expressing the found rule. When the controlling portion 502 executes the training program 532, parameters of an inference program are adjusted by machine training based on the training data 434. As a result, the trained model M is generated. The controlling portion 502 stores the generated trained model M in the storage portion 503.

The machine training algorithm is not particularly limited as long as it is supervised training and is, for example, a decision tree, a nearest neighbor algorithm, a simple Bayesian classifier, a support vector machine, or a neural network. Therefore, the trained model M includes a decision tree, a nearest neighbor algorithm, a simple Bayesian classifier, a support vector machine, or a neural network.

The neural network includes an input layer, a single or plurality of intermediate layers, and an output layer. Specifically, the neural network is a deep neural network (DNN), a recurrent neural network (RNN), or a convolutional neural network (CNN) and performs deep training. For example, the deep neural network includes an input layer, a plurality of intermediate layers and an output layer.

As described above, the machine training algorithm is not particularly limited but is a dynamic-inner partial least squares (DiPLS) regression in the first preferred embodiment. DiPLS is an improved algorithm based on PLS (partial least squares method) which is hardly affected by multicollinearity. Specifically, DiPLS is an algorithm obtained by improving PLS so that a variable such as a rotational speed can be added as an explanatory variable in consideration of a time delay. By using DiPLS or PLS as a machine training algorithm, even in a case where there is a similar tendency (a high correlation coefficient) between the explanatory variables (the detection results obtained by the first processing sensor 50) as in the first preferred embodiment, the regression expression is hardly affected by multicollinearity, and hence it is possible to suppress the regression expression from becoming unstable. The machine training algorithm may be PLS instead of DiPLS, a long short term memory (LSTM), or another algorithm.

The training apparatus 500 further includes a display portion 504, an input portion 505, and a communication portion 506.

The display portion 504 displays various screens and various types of information. The display portion 504 is, for example, a liquid crystal display or an organic EL display. The display portion 504 may display an input screen for inputting various data to the controlling portion 502.

The input portion 505 receives an input from the user and outputs various types of information to the controlling portion 502. The input portion 505 includes, for example, a touch panel and a pointing device. The input portion 505 may receive an input of an instruction to generate the trained model M.

The communication portion 506 is connected to a network and communicates with an external device. The network includes, for example, the Internet, a LAN, a public telephone network, and a short-range wireless network. The communication portion 506 is a communication device, for example, a network interface controller. In the first preferred embodiment, the communication portion 506 executes communication with the training apparatus 500 and the substrate processing apparatus 100. The communication portion 506 receives the training data 434 from the training data generation apparatus 400. In addition, the communication portion 406 transmits the trained model M to the substrate processing apparatus 100.

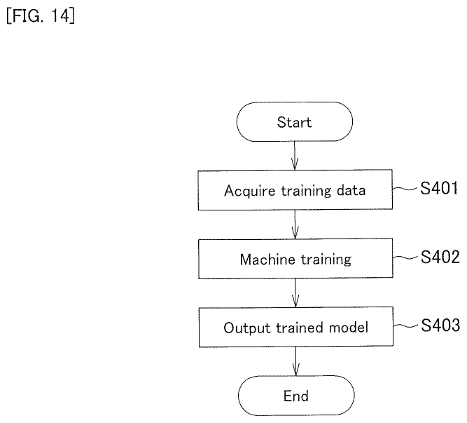

Next, a training method of the first preferred embodiment and a method of generating the trained model M will be described with reference to FIGS. 13 and 14. FIG. 14 is a flowchart illustrating a training method and a method of generating the trained model M according to the first preferred embodiment. The training method of the training data 434 includes steps S401 and S402. The method of generating the trained model M includes steps S401 to S403. Steps S401 to S403 are executed by the controlling portion 502. Note that step S401 is an example of a “step of acquiring training data” according to the present invention. Further, step S402 is an example of a “step of machine training” according to the present invention. Further, steps S402 and S403 are an example of “a step of generating a trained model by machine training” according to the present invention.

As illustrated in FIG. 14, in step S401, the controlling portion 502 acquires the training data 434 from the storage portion 503.

Next, in step S402, the controlling portion 502 performs machine training by inputting the training data 434 to the training program 532.

In step S403, the controlling portion 502 outputs a model (one or more functions) to which a plurality of trained parameters (coefficients) are applied as the trained model M. The storage portion 503 stores the trained model M. As a result, the training method ends, and the trained model M is generated.

### First Modified Example

Next, the substrate processing training system 1000 according to Modified Example 1 of the first preferred embodiment will be described. Modified Example 1 will exemplify a case where the trained model M is generated by machine training based on the first detection result and the second detection result indicated using a three-dimensional orthogonal coordinate system.

In Modified Example 1, the first training sensor 50L detects a wind speed and a wind direction with three values, namely, a wind speed, an azimuth angle (0° to 360°), and a depression angle (0° to 180°). Similarly to the first training sensor 50L, the second training sensor 60L and the first processing sensor 50 detect a wind speed and a wind direction with three values, namely, a wind speed, an azimuth angle (0° to 360°), and a depression angle (0° to 180°).

In this case, in generating the trained model M, for example, if azimuth angles are used as the first detection result and the second detection result, the estimation accuracy of the trained model M may deteriorate due to discontinuity near 0° and 360°. Therefore, in Modified Example 1, by indicating the first detection result and the second detection result using a three-dimensional orthogonal coordinate system, a decrease in estimation accuracy is suppressed.

Specifically, the three-dimensional orthogonal coordinate system includes, for example, X-, Y-, and Z-coordinates. The controlling portion 402 of the training data generation apparatus 400 converts the three values detected by the first training sensor 50L into data using an X-coordinate, a Y-coordinate, and a Z-coordinate. Similarly, the controlling portion 402 converts the three values detected by the second training sensor 60L into data using an X-coordinate, a Y-coordinate, and a Z-coordinate. Then, the controlling portion 402 generates the training data 434 by using the first detection result and the second detection result indicated by using a three-dimensional orthogonal coordinate system (X-, Y-, and Z-coordinates).

Specifically, the controlling portion 502 of the training apparatus 500 generates the trained model M by inputting the training data 434 generated by using the three-dimensional orthogonal coordinate system to the training program 532. The trained model M is generated by machine training based on the first detection result and the second detection result indicated by using the three-dimensional orthogonal coordinate system.

The first controlling portion 102 of the substrate processing apparatus 100 inputs the detection result obtained by the first processing sensor 50 indicated using the three-dimensional orthogonal coordinate system to the trained model M. Thereby, the first controlling portion 102 acquires the estimated wind speed and the estimated wind direction indicated using the three-dimensional orthogonal coordinate system.

Other configurations and other methods (the method of generating training data 434, a training method, a method of generating a trained model m, and an estimation method) according to the first modification are similar to those of the first preferred embodiment.

According to Modified Example 1, as described above, the trained model M is generated by machine training based on the first detection result and the second detection result indicated by using the three-dimensional orthogonal coordinate system. Therefore, it is possible to suppress a decrease in the estimation accuracy of the trained model M.

Other effects of Modified Example 1 are the same as those of the first preferred embodiment.

### Second Modified Example

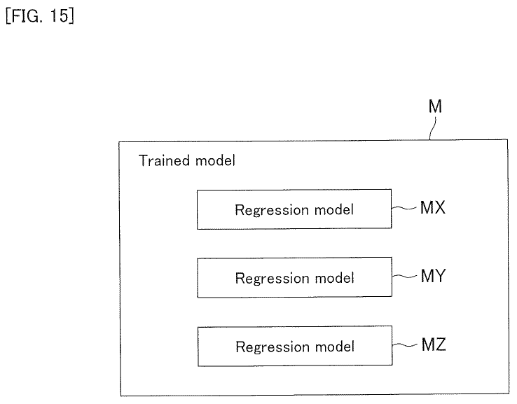

Next, the substrate processing training system 1000 according to Modified Example 2 will be described with reference to FIG. 15. Modified Example 2 will exemplify a case where the trained model M has a regression model for each of three coordinates. FIG. 15 is a diagram illustrating the trained model M according to Modified Example 2.

As illustrated in FIG. 15, in Modified Example 2, the trained model M includes a regression model MX, a regression model MY, and a regression model MZ. The regression model MX is a regression model for estimating the wind speed of the X-coordinate (in other words, the X component of the wind speed) at the second position during processing P1. The regression model MY is a regression model for estimating the wind speed of the Y-coordinate (in other words, the Y component of the wind speed) at the second position during processing P1. The regression model MZ is a regression model for estimating the wind speed of the Z-coordinate (in other words, the Z component of the wind speed) at the second position during processing P1.

For example, the regression model MX is generated on the basis of the detection results regarding all the coordinates (all of X-, Y, and Z-coordinates) among the first detection result and the second detection result. The first controlling portion 102 of the substrate processing apparatus 100 inputs the detection results regarding all the coordinates (all of the X-, Y-, and Z-coordinates) among the detection results obtained by the first processing sensor 50 to the regression model MX. Thereby, the first controlling portion 102 acquires the estimated wind speed at the X-coordinate at the second position during processing P1.

The regression model MY and the regression model MZ are also similar to the regression model MX. That is, each of the regression model MY and the regression model MZ is generated on the basis of the detection results regarding all the coordinates (all of the X-, Y-, and Z-coordinates) among the first detection result and the second detection result. The first controlling portion 102 of the substrate processing apparatus 100 inputs the detection results regarding all the coordinates (all of the X-, Y-, and Z-coordinates) among the detection results obtained by the first processing sensor 50 to each of the regression model MY and the regression model MZ. Thereby, the first controlling portion 102 acquires the estimated wind speed at the Y-coordinate and the estimated wind speed at the Z-coordinate at the second position during processing P1.

Other configurations and other methods (a method of generating the training data 434, a training method, a method of generating the trained model M, and an estimation method) according to Modified Example 2 are similar to those of Modified Example 1.

In Modified Example 2, as described above, the trained model M includes the regression models MX, MY, and MZ. The first controlling portion 102 inputs the detection result obtained by the first processing sensor 50 indicated using the three-dimensional orthogonal coordinate system to each of the regression models MX, MY, and MZ and acquires the estimated wind speed for each of the three coordinates. Therefore, the estimation accuracy of the trained model M can be improved.

Other effects of Modified Example 2 are the same as those of Modified Example 1.

### Modified Example 3

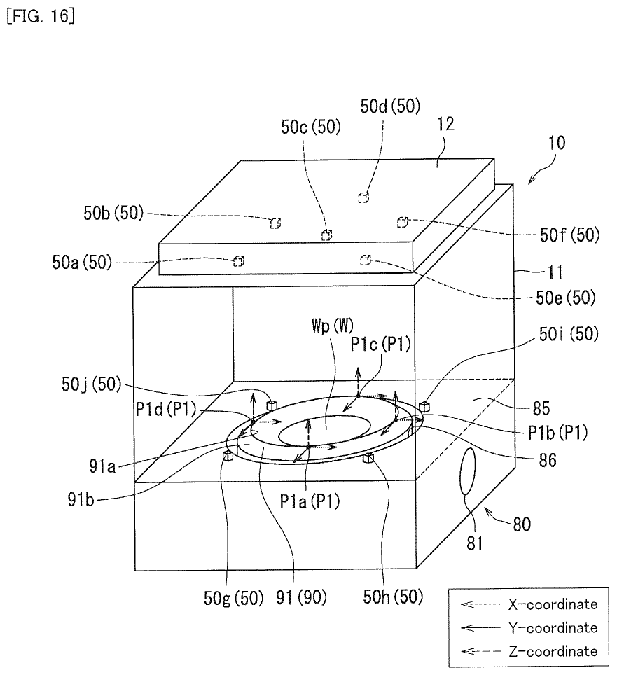

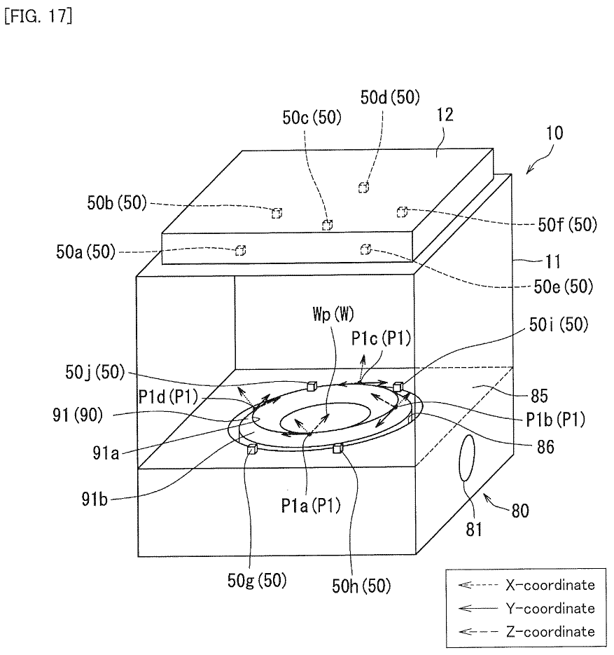

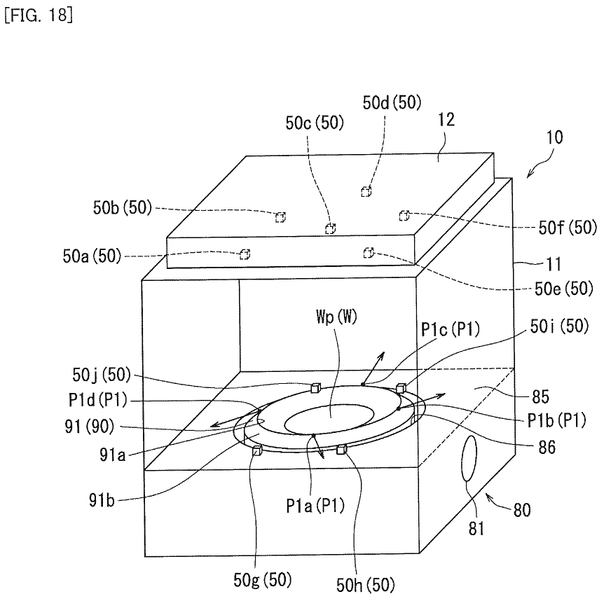

Next, the substrate processing training system 1000 according to Modified Example 3 will be described with reference to FIGS. 16 to 18. Modified Example 3 will exemplify a case where the acquired estimated wind speed and estimated wind direction are displayed on the display portion 104 using a coordinate system based on each of the second training sensors 60L. FIG. 16 is a diagram illustrating an example of a coordinate system based on the processing chamber 11 according to Modified Example 3. FIG. 17 is a diagram illustrating an example of a coordinate system based on each of the second training sensors 60L according to Modified Example 3. FIG. 18 is a diagram showing an example of an image showing the estimated wind speed and the estimated wind direction using a coordinate system based on each of the second training sensors 60L (see FIG. 5) of Modified Example 3.

In Modified Example 3, for example, the plurality of second training sensors 60L (see FIG. 5) are disposed rotationally symmetrically about the rotational axis AX. That is, all of the detection surfaces of the plurality of second training sensors 60L are disposed to, for example, face radially outward or radially inward. Therefore, for example, in a case where airflow flowing from the radially inner side to the radially outer side is generated at each second position during training, the detection results of the respective training second sensors 60L show the same tendency.

On the other hand, when the estimated wind speed and the estimated wind direction acquired using the trained model M are displayed on the display portion 104 using the coordinate system based on the processing chamber 11 as illustrated in FIG. 16, the wind directions at the second positions during processing P1 are substantially the same. That is, for example, the airflow does not flow from the radially inner side to the radially outer side. Therefore, when an image indicating the estimated wind speed and the estimated wind direction is displayed on the display portion 104 using the coordinate system based on the processing chamber 11 as illustrated in FIG. 16, the user may feel uneasy.

Therefore, in Modified Example 3, the first controlling portion 102 of the substrate processing apparatus 100 converts the acquired estimated wind speed and estimated wind direction from the coordinate system based on the processing chamber 11 as illustrated in FIG. 16 to the coordinate system based on each of the second training sensors 60L as illustrated in FIG. 17.

Then, as illustrated in FIG. 18, the first controlling portion 102 causes the display portion 104 to display the estimated wind speed and the estimated wind direction after conversion. Thereby, for example, an image indicating the airflow flowing from the radially inner side to the radially outer side is displayed at each of the second positions during processing P1. At this time, in Modified Example 3, the first controlling portion 102 combines the estimated wind speed at an X-coordinate, the estimated wind speed at a Y-coordinate, and the estimated wind speed at a Z-coordinate for each of the second positions during processing P1 and displays the combined result on the display portion 104.

Other configurations and other methods (a method of generating the training data 434, a training method, a method of generating the trained model M, and an estimation method) according to Modified Example 3 are similar to those of Modified Example 2.

In Modified Example 1, as described above, the first controlling portion 102 causes the display portion 104 to display the acquired estimated wind speed and estimated wind direction using the coordinate system based on each of the second training sensors 60L. Therefore, it is possible to prevent the user from feeling uneasy about the display portion 104.

Other effects of Modified Example 3 are similar to those of Modified Example 2.

### Second Preferred Embodiment

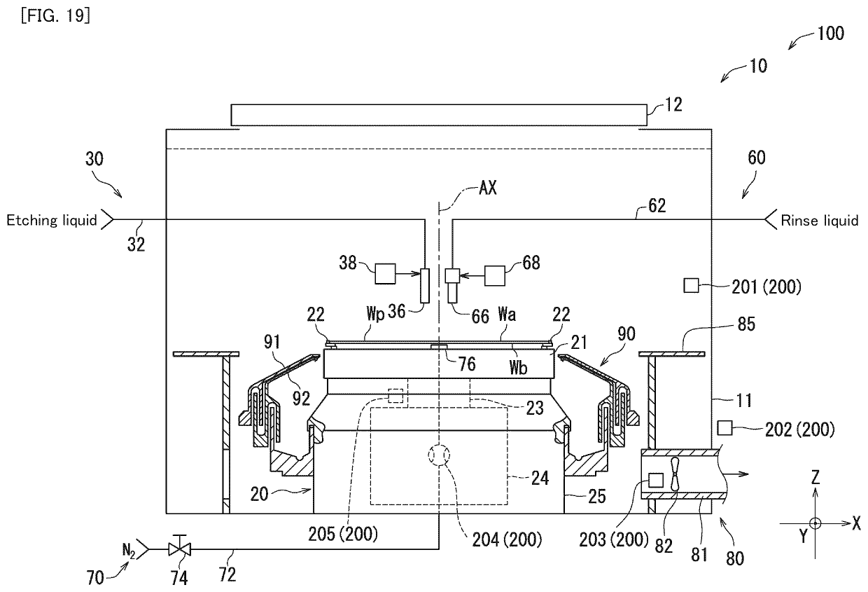

Next, substrate processing training system 1000 according to the second preferred embodiment of the present invention will be described with reference to FIG. 19. FIG. 19 is a schematic diagram of the processing unit 10 according to the second preferred embodiment. As in the first preferred embodiment, the substrate processing training system 1000 according to the second preferred embodiment includes a substrate processing apparatus 100, a substrate processing apparatus 100L, a training data generation apparatus 400, and a training apparatus 500.

As illustrated in FIG. 19, in the second preferred embodiment, the processing unit 10 of the substrate processing apparatus 100 further includes a processing detecting portion 200. The processing detecting portion 200 detects at least one of the atmospheric pressure in or around the processing chamber 11, the rotation speed of a processing target substrate Wp, the flow rate or the supply pressure of the gas supplied into the processing chamber 11, and the flow rate or the exhaust pressure of the gas discharged from the processing chamber 11. In the second preferred embodiment, the processing detecting portion 200 includes an internal pressure sensor 201, an external pressure sensor 202, an exhaust pressure sensor 203, a flowmeter 204, and a speed sensor 205.

The internal pressure sensor 201 and the external pressure sensor 202 detect the atmospheric pressure in or around the processing chamber 11. The exhaust pressure sensor 203 detects the flow rate or the exhaust pressure of the gas discharged from the processing chamber 11. The flowmeter 204 detects the flow rate or the supply pressure of the gas supplied into the processing chamber 11. The speed sensor 205 detects the rotation speed of the processing target substrate Wp. Hereinafter, a specific description will be given.

The internal pressure sensor 201 is disposed in the processing chamber 11. The internal pressure sensor 201 detects the pressure (atmospheric pressure) of the gas in the processing chamber 11. The internal pressure sensor 201 outputs a detection result to the first controlling portion 102. The internal pressure sensor 201 is not particularly limited but is disposed, for example, a position where the wind speed of the gas is low. In the second preferred embodiment, the internal pressure sensor 201 is disposed in the vicinity of the inner wall of the processing chamber 11. Furthermore, the internal pressure sensor 201 includes, for example, a pressure-sensitive element that detects the pressure of gas.

The external pressure sensor 202 is disposed outside the processing chamber 11. The external pressure sensor 202 detects the pressure (atmospheric pressure) of the gas outside the processing chamber 11. The external pressure sensor 202 outputs a detection result to the first controlling portion 102. The external pressure sensor 202 is not particularly limited but is disposed, for example, at a position where the wind speed of the gas is low. In the second preferred embodiment, the external pressure sensor 202 is disposed in the vicinity of the outer wall of the processing chamber 11. The external pressure sensor 202 is disposed, for example, around the exhaust pipe 81. Furthermore, the external pressure sensor 202 includes, for example, a pressure-sensitive element that detects the pressure of the gas.

The exhaust pressure sensor 203 detects the pressure (atmospheric pressure) of the gas discharged from the inside of the processing chamber 11 to the outside. The exhaust pressure sensor 203 outputs a detection result to the first controlling portion 102. The exhaust pressure sensor 203 is not particularly limited but is disposed in, for example, the exhaust pipe 81. Note that the exhaust pressure sensor 203 may be disposed around the inlet of the exhaust pipe 81 or around the outlet of the exhaust pipe 81. Furthermore, the exhaust pressure sensor 203 includes, for example, a pressure-sensitive element that detects the pressure of the gas.

The flowmeter 204 measures the supply amount of inert gas supplied from the inert gas supplying portion 70 into the processing chamber 11. The flowmeter 204 is disposed in a piping 72. The flowmeter 204 detects the flow rate of inert gas passing through the piping 72. The flowmeter 204 outputs a detection result to the first controlling portion 102.

The speed sensor 205 detects the rotation speed of a substrate W (rotation speed of a shaft 23). The speed sensor 205 outputs a detection result to the first controlling portion 102. The speed sensor 205 is not particularly limited but for example, detects the rotation speed of a spin base 21 or the shaft 23. Furthermore, the speed sensor 205 is not particularly limited, and for example, an electromagnetic sensor, a Hall element sensor, an optical sensor, an induction sensor, or the like can be used.

The detection intervals of the internal pressure sensor 201, the external pressure sensor 202, the exhaust pressure sensor 203, the flowmeter 204, and the speed sensor 205 are not particularly limited but are, for example, 0.1 sec or more and 10 sec or less. In the second preferred embodiment, the internal pressure sensor 201, the external pressure sensor 202, the exhaust pressure sensor 203, the flowmeter 204, and the speed sensor 205 detect about every 1 sec.

Other configurations of the substrate processing apparatus 100 and the processing unit 10 according to the second preferred embodiment are similar to those of the first preferred embodiment.

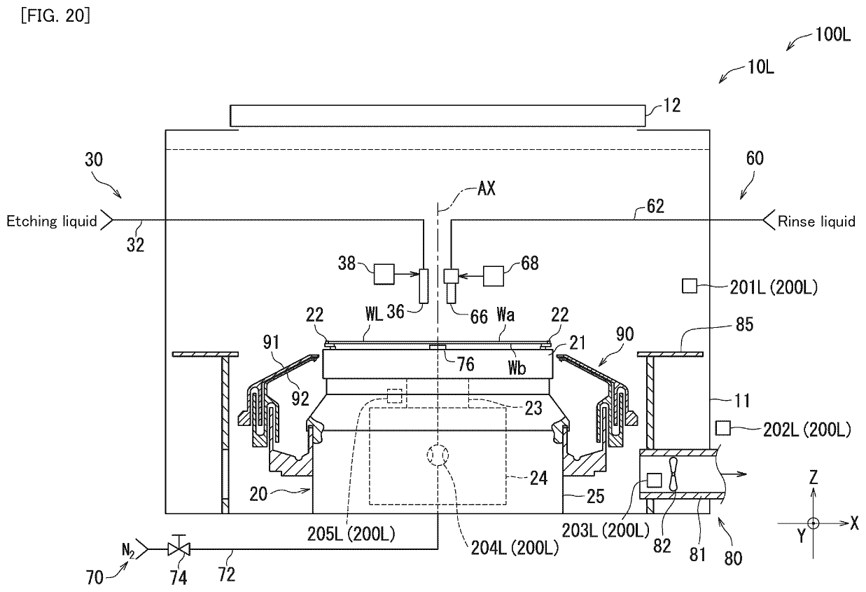

Next, the substrate processing apparatus 100L according to the second preferred embodiment will be described with reference to FIG. 20. FIG. 20 is a schematic diagram of a processing unit 10L of the substrate processing apparatus 100L according to the second preferred embodiment. The substrate processing apparatus 100L further includes a training detecting portion 200L. The training detecting portion 200L is configured similarly to the processing detecting portion 200. Specifically, the training detecting portion 200L detects at least one of the air pressure in or around the training chamber 11L, the rotation speed of the training target substrate WL, the flow rate or the supply pressure of the gas supplied into the training chamber 11L, and the flow rate or the exhaust pressure of the gas discharged from the training chamber 11L. In the second preferred embodiment, the training detecting portion 200L includes an internal pressure sensor 201L, an external pressure sensor 202L, an exhaust pressure sensor 203L, a flowmeter 204L, and a speed sensor 205L.

The internal pressure sensor 201L is disposed in the training chamber 11L. The internal pressure sensor 201L detects the pressure of the gas in the training chamber 11L, and outputs the detection result to the second controlling portion 102L.

The external pressure sensor 202L is disposed outside the training chamber 11L. The external pressure sensor 202L detects the pressure of the gas outside the training chamber 11L and outputs the detection result to the second controlling portion 102L.

The exhaust pressure sensor 203L detects the pressure of the gas discharged from the inside of the training chamber 11L to the outside and outputs the detection result to the second controlling portion 102L.

The flowmeter 204L measures the supply amount of the inert gas supplied from the inert gas supplying portion 70 into the training chamber 11L and outputs the detection result to the second controlling portion 102L.

The speed sensor 205L detects the rotation speed of the substrate W (the rotation speed of the shaft 23) and outputs the detection result to the second controlling portion 102L.

Other structures, operations, and placement positions of the internal pressure sensor 201L, the external pressure sensor 202L, the exhaust pressure sensor 203L, the flowmeter 204L, and the speed sensor 205L of the substrate processing apparatus 100L are similar to those of the internal pressure sensor 201, the external pressure sensor 202, the exhaust pressure sensor 203, the flowmeter 204, and the speed sensor 205 of the substrate processing apparatus 100.

In the second preferred embodiment, in addition to the first detection result, the second detection result, and the processing condition for training, the second controlling portion 102L also transmits detection results (to be sometimes referred to as a third detection result) obtained by the internal pressure sensor 201L, the external pressure sensor 202L, the exhaust pressure sensor 203L, the flowmeter 204L, and the speed sensor 205L to the training data generation apparatus 400.

Other structures of the substrate processing apparatus 100L and the processing unit 10L according to the second preferred embodiment are the same as those of the first preferred embodiment.

In the second preferred embodiment, the trained model M is generated by machine training based on third detection results (the detection results obtained by the internal pressure sensor 201L, the external pressure sensor 202L, the exhaust pressure sensor 203L, the flowmeter 204L, and the speed sensor 205L) in addition to the first detection result and the second detection result. The detection targets of the internal pressure sensor 201, the external pressure sensor 202, the exhaust pressure sensor 203, the flowmeter 204, and the speed sensor 205 all affect the wind speed and the wind direction in the processing chamber 11. Therefore, the estimation accuracy can be improved by generating a trained model M by machine training based on the third detection results (the detection results obtained by the internal pressure sensor 201L, the external pressure sensor 202L, the exhaust pressure sensor 203L, the flowmeter 204L, and the speed sensor 205L).

Next, a training data generation apparatus 400 according to the second preferred embodiment will be described. In the second preferred embodiment, a controlling portion 402 generates training data 434 in association with the third detection results in addition to the first detection result, the second detection result, and the training processing condition.

Other configurations of the training data generation apparatus 400 according to the second preferred embodiment are similar to those of the first preferred embodiment.

Next, a method of generating the training data 434 according to the second preferred embodiment will be described. In step S301 illustrated in FIG. 12, the controlling portion 402 acquires the third detection results in addition to the first detection result, the second detection result, and the training processing condition.

In step S302, the controlling portion 402 generates the training data 434 by associating the third detection results in addition to the first detection result, the second detection result, and the training processing condition and stores the training data in the storage portion 403.

As described above, the generation of the training data 434 ends. Other methods for generating the training data 434 according to the second preferred embodiment are similar to those of the first preferred embodiment.

The configuration of the training apparatus 500, the training method, and the method of generating the trained model M according to the second preferred embodiment are similar to those of the first preferred embodiment.

The preferred embodiments of the present invention have been described with reference to the accompanying drawings. However, the present invention is not limited to the above preferred embodiment, and can be implemented in various modes without departing from the gist thereof. Also, it is possible to modify, as appropriate, the plurality of constituent elements disclosed in the preferred embodiments described above. For example, a certain constituent element among all constituent elements of a certain preferred embodiment may be added to the constituent elements of another preferred embodiment or some constituent elements among all constituent elements of a certain preferred embodiment may be deleted from the preferred embodiment.

The drawings mainly illustrate the respective constituent elements schematically to facilitate understanding of the invention and there are cases where thicknesses, lengths, numbers, intervals, etc., of the respective constituent elements illustrated differ from actual ones due to convenience of drawing preparation. Also, the arrangements of the respective constituent elements indicated in the preferred embodiments described above are but an example, are not restricted in particular, and can obviously be changed variously within a scope of practically not deviating from the effects of the present invention.

For example, the first preferred embodiment and the second preferred embodiment described above have exemplified the case where the user checks the estimated wind speed and the estimated wind direction displayed on the display portion 104 and changes the processing condition. However, the present invention is not limited to this. For example, when the estimated wind speed and the estimated wind direction are out of predetermined ranges, the first controlling portion 102 may automatically change the processing condition. In this case, the first controlling portion 102 may not display the estimated wind speed and the estimated wind direction on the display portion 104. In addition, the first controlling portion 102 may automatically stop the processing.

The first preferred embodiment and the second preferred embodiment have exemplified the case where the first controlling portion 102 acquires both the estimated wind speed and the estimated wind direction. However, the present invention is not limited to this. The first controlling portion 102 may acquire only one of the estimated wind speed and the estimated wind direction. In other words, the trained model M may output only one of the estimated wind speed and the estimated wind direction.

The first preferred embodiment and the second preferred embodiment described above have exemplified the case where the substrate processing apparatus 100 includes a rinse liquid supplying portion 60 (cleaning liquid supplying portion). However, the present invention is not limited to this. For example, the present invention can also be applied to a substrate processing apparatus that performs drying, heating, etching, or the like on a substrate.

The first preferred embodiment and the second preferred embodiment described above have exemplified the case where the second position during processing P1 is a position on the cup 90. However, the present invention is not limited to this. For example, the second position during processing P1 may be a position other than positions on the cup 90.

Furthermore, for example, Modified Example 1 has exemplified the case where the first training sensor 50L, the second training sensor 60L, and the first processing sensor 50 detect a wind direction with two values, namely, an azimuth angle (0° to 360°) and a depression angle (0° to 180°). However, the present invention is not limited to this. The first training sensor 50L, the second training sensor 60L, and the first processing sensor 50 may output, for example, detection results using a three-dimensional orthogonal coordinate system.

Modified Example 2 has exemplified the case where the trained model M has a regression model for each of three coordinates. However, the present invention is not limited to this. For example, the wind speeds at all the coordinates (X-, Y-, and Z-coordinates) may be estimated by one regression model.

### INDUSTRIAL APPLICABILITY

The present invention is useful in the field of processing substrates.

### REFERENCE SIGNS LIST

11: Processing chamber
11L: Training chamber
20: Substrate holding portion
50, 50a~50j: First processing sensor
50L, 50La~50Lj: First training sensor
60: Rinse liquid supplying portion (cleaning liquid supplying portion)
60L, 60La~60Ld: Second training sensor
90, 91, 92: Cup
100: Substrate processing apparatus
102: First controlling portion (controlling portion)
104: Display portion
105: Input portion
200: Processing detecting portion
200L: Training detecting portion
201: Internal pressure sensor (processing detecting portion)
201L: Internal pressure sensor (training detecting portion)
202: External pressure sensor (processing detecting portion)
202L: External pressure sensor (training detecting portion)
203: Exhaust pressure sensor (processing detecting portion)
203L: Exhaust pressure sensor (training detecting portion)
204: Flowmeter (processing detecting portion)
204L: Flowmeter (training detecting portion)
205: Speed sensor (processing detecting portion)
205L: Speed sensor (training detecting portion)
434: Training data
500: Training apparatus
502: Controlling portion (training portion)
503: Storage portion
532: Training program
M: Trained model
MX, MY, MZ: Regression model
P1, P1a~P1d: Second position during processing
Wp: Processing target substrate

1. A substrate processing apparatus comprising:
a substrate holder that holds and rotates a processing target substrate;
a processing chamber that accommodates the substrate holder;
a first processing sensor that is disposed in or around the processing chamber and detects at least one of a wind speed and a wind direction at a first position during processing in or around the processing chamber; and
a controller that is configured or programmed to input a detection result obtained by the first processing sensor to a trained model and acquire at least one of an estimated wind speed and an estimated wind direction at a second position during processing in the processing chamber,
wherein the trained model is generated by machine training based on a first detection result obtained by a first training sensor that detects at least one of a wind speed and a wind direction at a first position during training in or around a training chamber and a second detection result obtained by a second training sensor that detects at least one of a wind speed and a wind direction at a second position during training in the training chamber.

2. The substrate processing apparatus according to claim 1, further comprising a cleaning liquid supplying portion including a nozzle that supplies a cleaning liquid to the processing target substrate,
wherein the controller is configured or programmed to input a detection result obtained by the first processing sensor at time of cleaning to the trained model and acquire at least one of the estimated wind speed and the estimated wind direction at the time of cleaning.

3. The substrate processing apparatus according to claim 1, further comprising a cup that is disposed around the substrate holder and receives a processing liquid discharged from the processing target substrate,
wherein the second position during processing is a position on the cup.

4. The substrate processing apparatus according to claim 1, wherein the trained model is generated by machine training based on the first detection result and the second detection result indicated using a three-dimensional orthogonal coordinate system, and
the controller is configured or programmed to input a detection result obtained by the first processing sensor indicated using a three-dimensional orthogonal coordinate system to the trained model and acquires at least one of the estimated wind speed and the estimated wind direction indicated using the three-dimensional orthogonal coordinate system.

5. The substrate processing apparatus according to claim 4, wherein the trained model includes a regression model for each of three coordinates, and
the controller is configured or programmed to input a detection result obtained by the first processing sensor indicated using a three-dimensional orthogonal coordinate system to each of the regression models and acquire the estimated wind speed for each of the three coordinates.

6. The substrate processing apparatus according to claim 1, further comprising a display that displays at least one of the estimated wind speed and the estimated wind direction.

7. The substrate processing apparatus according to claim 6, wherein the controller is configured or programmed to cause the display to display at least one of the acquired estimated wind speed and estimated wind direction using a coordinate system based on each of the second training sensors.

8. The substrate processing apparatus according to claim 6, further comprising an input to accept an input of a processing condition for processing the processing target substrate,
wherein the input accepts the input of the processing condition that can change at least one of the estimated wind speed and the estimated wind direction.

9. The substrate processing apparatus according to claim 1, further comprising a processing detector,
wherein the processing detector detects at least one of an atmospheric pressure in or around the processing chamber, a rotation speed of the processing target substrate, a flow rate or a supply pressure of gas supplied into the processing chamber, and a flow rate or an exhaust pressure of gas discharged from the processing chamber,
the trained model is generated by machine training based on the first detection result, the second detection result, and the detection result obtained by the training detector,
the training detector detects at least one of an atmospheric pressure in or around the training chamber, a rotation speed of the training target substrate, a flow rate or a supply pressure of gas supplied into the training chamber, and a flow rate or an exhaust pressure of gas exhausted from the training chamber, and
the controller is configured or programmed to inputs a detection result obtained by the first processing sensor and a detection result obtained by the processing detector to the trained model and acquire at least one of the estimated wind speed and the estimated wind direction at the second position during processing.

10. An estimation method comprising:
detecting at least one of a wind speed and a wind direction at a first position during processing in or around a processing chamber accommodating a substrate holder that holds and rotates a processing target substrate; and
inputting a detection result of detecting at least one of the wind speed and the wind direction to a trained model and acquiring at least one of an estimated wind speed and an estimated wind direction at a second position during processing in the processing chamber,
wherein the trained model is generated by machine training based on a first detection result obtained by a first training sensor that detects at least one of a wind speed and a wind direction at a first position during training in or around a training chamber and a second detection result obtained by a second training sensor that detects at least one of a wind speed and a wind direction at a second position during training in the training chamber.

11. A method of generating training data, the method comprising:
acquiring a first detection result of detecting at least one of a wind speed and a wind direction at a first position during training in or around a training chamber accommodating a substrate holder;
acquiring a second detection result of detecting at least one of a wind speed and a wind direction at a second position during training in the training chamber; and
storing the first detection result and the second detection result in association with each other in a storage as training data.

12. A training method comprising:
acquiring training data generated according to the method of generating training data according to claim 11; and
performing machine training by inputting the training data to a training program.

13. A training apparatus comprising:
a storage that stores training data generated according to the method of generating training data according to claim 11; and
a processor that performs machine training by inputting the training data to a training program.

14. A method of generating a trained model, the method comprising:
acquiring training data generated according to the method of generating training data according to claim 11; and
generating a trained model by machine training based on the training data.

15. A non-transitory computer-readable storage medium storing a computer program to be executed by a computer, the computer program including a trained model generated by machine training based on training data generated according to the method of generating training data according to claim 11.

16. The substrate processing apparatus according to claim 1, wherein
the first position during training is a position at the training chamber corresponding to the first position during processing, and
the second position during training is a position at the training chamber corresponding to the second position during processing.

17. The estimation method according to claim 10, wherein
the first position during training is a position at the training chamber corresponding to the first position during processing, and
the second position during training is a position at the training chamber corresponding to the second position during processing.
